(19) United States
(12) Patent Application Publication
(10) Pub. No.: US 2007/0090417 A1
(43) Pub. Date: Apr. 26, 2007

(54) Semiconductor device and method for fabricating the same

(76) Inventor: Chiaki Kudo, Hyogo (JP)

Correspondence Address: MCDERMOTT WILL & EMERY LLP, 600 13TH STREET, N.W., WASHINGTON, DC, 20005-3096, US

(21) Appl. No.: 11/495,662

(22) Filed: Jul. 31, 2006

(30) Foreign Application Priority Data
Oct. 26, 2005 (JP) 2005-311759

(51) Int. Cl. H01L 29/76

(52) U.S. Cl. 257/288

(57) ABSTRACT

A semiconductor device includes a first MIS transistor including a first gate electrode fully silicided with a metal. With the first MIS transistor includes: a first gate insulating film formed on a semiconductor region; the first gate electrode formed on the first gate insulating film; a first sidewall spacer formed on a side of the first gate electrode; and a second sidewall spacer formed at the side of the first gate electrode with the first sidewall spacer interposed therebetween; the first sidewall spacer and the second sidewall spacer have different etching characteristics. The first sidewall spacer has an upper end lower than an upper surface of the first gate electrode and an upper end of the second sidewall spacer.

### CROSS-REFERENCE TO RELATED APPLICATION

The disclosure of Japanese Patent Applications No. 2005-311759 filed in Japan on Oct. 26, 2005 and No. 2006-149399 filed in Japan on May 30, 2006 including specification, drawings and claims is incorporated herein by reference in its entirety.

### BACKGROUND OF THE INVENTION

The present invention relates to semiconductor devices and methods for fabricating the devices, and particularly relates to semiconductor devices including field-effect transistors with fully-silicided (FUSI) structures and methods for fabricating the devices.

The integration degree of semiconductor elements integrated in a semiconductor integrated circuit device has increased to date. For example, a technique for miniaturizing a gate electrode of a metal-insulator-semiconductor (MIS) field-effect transistor (FET) and reducing the electrical thickness of a gate insulating film by using a material with a high dielectric constant as an insulating material of the gate insulating film is being used. However, it is generally impossible to prevent depletion from being formed in polysilicon used for the gate electrode even by impurity implantation, resulting in that this depletion increases the electrical thickness of the gate insulating film. This hinders enhancement of FET performance.

In recent years, gate electrode structures capable of preventing formation of depletion in gate electrodes have been proposed. Specifically, a fully-silicided (FUSI) structure obtained by causing reaction between a silicon material forming a gate electrode and a metal material and thereby changing the entire silicon material into silicide is reported as an effective technique for suppressing depletion in the gate electrode.

In T. Aoyama et al., IEEE, Proposal of New HfSiON CMOS Fabrication Process (HAMDAMA) for Low Standby Power Device, 2004 (hereinafter, referred to as Literature 1), a method for forming a FUSI structure is proposed. In K. Takahashi et al., IEEE, Dual Workfunction Ni-Silicide/HfSiON Gate Stacks by Phase-Controlled Full-Silicidation (PC-FUSI) Technique for 45 nm-node LSTP and LOP Devices, 2004 (hereinafter, referred to as Literature 2), different materials are used for FUSI electrodes in an n-FET and a p-FET, respectively, e.g., NiSi is used for the n-FET and Ni₃Si is used for the p-FET, is proposed.

FIGS. 23A through 23D illustrate cross-sectional structures of a main portion in process steps of forming FUSI electrodes in a method for fabricating conventional MISFETs disclosed in Literature 1.

First, as illustrated in FIG. 23A, an isolation film 2 is formed in an upper portion of a semiconductor substrate 1 made of silicon. Thereafter, a gate insulating film 3 and a conductive polysilicon film are formed in this order on an n-FET region A and a p-FET region B defined by the isolation film 2 in the semiconductor substrate 1. Subsequently, the polysilicon film is patterned, thereby forming a first gate-electrode film 4A and a second gate-electrode film 4B in the n-FET region A and the p-FET region B, respectively. Then, insulating sidewall spacers 5 are formed on the sides of the gate-electrode films 4A and 4B. Subsequently, using the sidewall spacers 5 as masks, source/drain regions 6 are formed in an active region of the semiconductor substrate 1. Thereafter, an interlayer insulating film 7 is formed over the semiconductor substrate 1 to cover the gate-electrode films 4A and 4B and the sidewall spacers 5. Then, chemical mechanical polishing (CMP), for example, is performed on the interlayer insulating film 7, thereby exposing the gate-electrode films 4A and 4B.

Next, as illustrated in FIG. 23B, a resist pattern 8 for exposing the p-FET region B is formed on the interlayer insulating film 7. Then, using the resist pattern 8 as a mask, an upper portion of the second gate-electrode film 4B exposed from the interlayer insulating film 7 in the p-FET region B is removed by etching.

Thereafter, as illustrated in FIG. 23C, the resist pattern 8 is removed, and then a metal film 9 made of nickel is deposited over the interlayer insulating film 7 from which the gate-electrode films 4A and 4B are exposed.

Then, as illustrated in FIG. 23D, heat treatment is performed on the semiconductor substrate 1 to cause reaction between the gate-electrode films 4A and 4B of polysilicon and the metal film 9, thereby forming a first gate electrode 10A having its upper portion silicided in the n-FET region A and a fully-silicided second gate electrode 10B in the p-FET region B. In Literature 1, the polysilicon gate-electrode film 4A partially remains in a lower portion of the first gate electrode 10A forming an n-FET, whereas the polysilicon gate-electrode film 4B does not remain in a lower portion of the second gate electrode 10B forming a p-FET and the entire second gate electrode 10B is changed to NiSi.

In Literature 2, a thick metal film is deposited so that the entire first gate electrode 10A is made of NiSi and the entire second gate electrode 10B is made of Ni₃Si.

The present inventor conducted various studies on conventional FUSI structures to find a phenomenon in which full silicidation nonuniformly occurs in a polysilicon film for forming a gate electrode in a MISFET during full silicidation of the gate electrode. This phenomenon is conspicuous especially when the gate length is relatively large. FIGS. 24A and 24B show this phenomenon.

As illustrated in FIG. 24A, a first gate-electrode film 4C made of polysilicon and a second gate-electrode film 4D made of polysilicon and having a gate length larger than that of the first gate-electrode film 4C are formed on an active region of a semiconductor substrate 1. In this case, metal atoms diffuse into polysilicon not only from a metal film 9 deposited over the gate-electrode films 4C and 4D but also from portions over sidewall spacers 5 and their neighboring portions. That is, metal is excessively supplied from portions of the metal film deposited over the both ends in the gate length direction of each of the gate-electrode films 4C and 4D, resulting in excessive silicidation in polysilicon near the sidewall spacers 5.

Accordingly, as illustrated in FIG. 24B, when the first gate-electrode film 4C having a relatively small gate length is fully silicided to form a first gate electrode 10C having a desired composition, the entire second gate-electrode film 4D having a relatively large gate length is not fully silicided. As a result, the second gate-electrode film 4D made of polysilicon partially remains in a lower portion of a silicided second gate electrode 10D.

On the other hand, when a second gate-electrode film 4D having a relatively large gate length is fully silicided to form a second gate electrode 10D, metal is excessively supplied to a first gate-electrode film 4C having a relatively small gate length. As a result, a first gate electrode 10C which is metal-rich as compared to the desired composition is formed.

In addition, to fully silicide the second gate-electrode film 4D having a relatively large gate length, metal is supplied only from a portion deposited over the sidewall spacers 5 to a middle portion of polysilicon forming the second gate-electrode film 4D apart from the sidewall spacers 5. On the other hand, metal is supplied to portions of polysilicon forming the second gate-electrode film 4D adjacent to the respective sidewall spacers 5 not only from portions on polysilicon but also from portions over the sidewall spacers 5 and their neighboring portions. Accordingly, portions of the second gate electrode 10D adjacent to the sidewall spacers 5 become metal-rich as compared to the middle portion thereof apart -from the sidewall spacers 5, so that the resulting composition is not uniform. In this manner, in a FET having a relatively large gate length, the composition of the gate electrode differs between portions near the sidewall spacers 5 and the middle portion, thus causing a variation of the threshold voltage of the FET.

In the case of applying the conventional full silicidation method to a resistor or an upper electrode of a capacitor, the resistance value varies in the resistor or the capacitance value varies in the capacitor.

### SUMMARY OF THE INVENTION

It is therefore an object of the present invention to provide a semiconductor device having a FUSI structure with a uniform composition irrespective of the gate length, and a method for fabricating the semiconductor device.

To achieve the object, in a semiconductor device and a method for fabricating the device according to the present invention, a sidewall spacer provided on the side of a gate electrode has a multilayer structure formed by stacking a first sidewall spacer and a second sidewall spacer in this order on the gate electrode. In this structure, a gap is formed between the second sidewall spacer and the side of the gate electrode by removing an upper portion of the first sidewall in contact with the gate electrode.

Specifically, in a semiconductor device according to the present invention is a semiconductor device including a first MIS transistor including a first gate electrode fully silicided with a metal. The first MIS transistor includes: a first gate insulating film formed on a semiconductor region; the first gate electrode formed on the first gate insulating film; a first sidewall spacer formed on a side of the first gate electrode; and a second sidewall spacer formed at the side of the first gate electrode with the first sidewall spacer interposed therebetween, the first sidewall spacer and the second sidewall spacer have different etching characteristics, and the first sidewall spacer has an upper end lower than an upper surface of the first gate electrode and an upper end of the second sidewall spacer.

In the semiconductor device, the upper end of the first sidewall spacer formed on the side of the first gate electrode is lower than the upper surface of the first gate electrode and the upper end of the second sidewall spacer, so that a gap is formed between the side of the first gate electrode and the second side wall. In a silicidation process in which a metal film is deposited over the sidewalls and the first gate electrode, this gap between each side of the first gate electrode and the second sidewall makes the deposited metal film isolated on the gate electrodes or reduces the thickness of the metal film. Accordingly, metal is supplied only from a portion located over the first gate electrode and is hardly supplied from other portions. As a result, the FUSI first gate electrodes has a uniform composition, irrespective of the size (i.e., the gate length) thereof.

In the semiconductor device, the upper end of the second sidewall spacer is preferably higher than the upper surface of the first gate electrode.

Preferably, the semiconductor device further includes a second MIS transistor including a second gate electrode fully silicided with the metal and having a gate length larger than that of the first gate electrode, wherein the second MIS transistor includes: a second gate insulating film formed on the semiconductor region; the second gate electrode formed on the second gate insulating film; a first sidewall spacer formed on a side of the second gate electrode; and a second sidewall spacer formed at the side of the second gate electrode with the first sidewall spacer interposed therebetween, the first sidewall spacer has an upper end lower than an upper surface of the second gate electrode and an upper end of the second sidewall spacer, and the first MIS transistor and the second MIS transistor are of an identical conductivity type.

In this case, the upper surface of the first gate electrode and the upper surface of the second gate electrode are preferably at an identical level from an upper surface of the semiconductor region.

In this case, the first gate electrode and the second gate electrode preferably have an identical composition.

Preferably, the semiconductor device further includes a third MIS transistor including a third gate electrode fully silicided with the metal, wherein the third MIS transistor includes: a third gate insulating film formed on the semiconductor region; the third gate electrode formed on the third gate insulating film; a first sidewall spacer formed on a side of the third gate electrode; and a second sidewall spacer formed at the side of the third gate electrode with the first sidewall spacer interposed therebetween, the first sidewall spacer has an upper end lower than an upper surface of the third gate electrode and an upper end of the second sidewall spacer, and the first MIS transistor and the third MIS transistor are of different conductivity types.

In this case, the first gate electrode and the third gate electrode preferably have different compositions.

Preferably, the semiconductor device further includes a resistor including a resistor element fully silicided with the metal, wherein the resistor includes: the resistor element formed on an isolation region defined in an upper portion of the semiconductor region; a first sidewall spacer formed on a side of the resistor element; and a second sidewall spacer formed at the side of the resistor element with the first sidewall spacer interposed therebetween, and the first sidewall spacer has an upper end lower than an upper surface of the resistor element and an upper end of the second sidewall spacer.

In this case, the first gate electrode and the resistor element have an identical composition.

Preferably, the semiconductor device farther includes a capacitor including an upper electrode fully silicided with the metal, wherein the capacitor includes: a capacitive insulating film formed on the semiconductor region; the upper electrode formed on the capacitive insulating film; a first sidewall spacer formed on a side of the upper electrode; and a second sidewall spacer formed at the side of the upper electrode with the first sidewall spacer interposed therebetween, and the first sidewall spacer has an upper end lower than an upper surface of the upper electrode and an upper end of the second sidewall spacer.

In this case, the first gate electrode and the upper electrode preferably have an identical composition.

A method for fabricating a semiconductor device according to the present invention is a method for fabricating a semiconductor device including a first MIS transistor including a first gate electrode on a first gate insulating film. The method includes the steps of: (a) forming the first gate insulating film on a semiconductor region; (b) forming a first gate silicon film on the first gate insulating film; (c) forming a first sidewall spacer on a side of the first gate silicon film; (d) forming a second sidewall spacer at the side of the first gate silicon film with the first sidewall spacer interposed therebetween; (e) etching the first sidewall spacer after the step (d) such that the first sidewall spacer has an upper end lower than an upper surface of the first gate silicon film and an upper end of the second sidewall spacer; (f) forming a metal film on the first gate silicon film after the step (e); and (g) fully siliciding the first gate silicon film with the metal film, thereby forming the first gate electrode.

With the method, etching is performed on the first sidewall spacer such that the upper end of the first sidewall spacer is lower than the upper surface of the first gate electrode. Accordingly, in a subsequent process step in which a metal film is formed over the second sidewall spacer and the first gate electrode, a gap is formed between each side of the first gate electrode and the second sidewall. This gap makes the metal film isolated on the first gate electrode or reduces the thickness of the metal film, so that metal is supplied only from a portion located over the first gate electrode and is hardly supplied from other portions. As a result, the FUSI first gate electrodes has a uniform composition, irrespective of the size (i.e., the gate length) thereof. In addition, with a conventional method, stress is applied to a semiconductor region because of the difference in expansion or shrinkage coefficient between a gate-electrode material and a sidewall-spacer material occurring during heat treatment for deposition of, for example, an interlayer insulating film. On the other hand, according to the present invention, this stress is greatly reduced by the gap formed on the side of the first gate electrode. Accordingly, variation of transistor characteristics caused by the stress due to full silicidation is prevented.

Preferably, in the method, the step (b) includes the step of forming a protective insulating film on the first gate silicon film, the step (c) includes the step of forming the first sidewall spacer on sides of the first gate silicon film and the protective insulating film, the step (d) includes the step of forming the second sidewall spacer at the sides of the first gate silicon film and the protective insulating film with the first sidewall spacer interposed therebetween, and the step (e) includes the step of etching the protective insulating film, thereby exposing the upper surface of the first gate silicon film.

Preferably, in the method, the semiconductor device further includes a second MIS transistor including, on a second gate insulating film, a second gate electrode having a gate length larger than that of the first gate electrode, the step (a) includes the step of forming the second gate insulating film on the semiconductor region; the step (b) includes the step of forming a second gate silicon film on the second gate insulating film; the step (c) includes the step of forming a first sidewall spacer on a side of the second gate silicon film, the step (d) includes the step of forming a second sidewall spacer at the side of the second gate silicon film with the first sidewall spacer interposed therebetween, the step (e) includes the step of etching the first sidewall spacer such that the first sidewall spacer has an upper end lower than an upper surface of the second gate silicon film and an upper end of the second sidewall spacer, the step (f) includes the step of forming the metal film on the second gate silicon film, and the step (g) includes the step of fully siliciding the second gate silicon film with the metal film, thereby forming the second gate electrode.

Preferably, in the method, the semiconductor device further includes a third MIS transistor including, on a third gate insulating film, a third gate electrode having a composition different from that of the first gate electrode, the step (a) includes the step of forming the third gate insulating film on the semiconductor region, the step (b) includes the step of forming a third gate silicon film on the third gate insulating film, the step (c) includes the step of forming a first sidewall spacer on a side of the third gate silicon film, the step (d) includes the step of forming a second sidewall spacer at the side of the third gate silicon film with the first sidewall spacer interposed therebetween, the step (e) includes the step of etching the first sidewall spacer such that the first sidewall spacer has an upper end lower than an upper surface of the third gate silicon film and an upper end of the second sidewall spacer, the step (f) includes the step of forming the metal film on the third gate silicon film, the step (g) includes the step of fully siliciding the third gate silicon film with the metal film, thereby forming the third gate electrode, and the method further includes the step of (h) etching the third gate silicon film such that the upper surface of the third gate silicon film is lower than the upper surface of the first gate silicon film, after the step (b) and before the step (f).

Preferably, in the method, the semiconductor device further includes a third MIS transistor including, on a third gate insulating film, a third gate electrode having a composition different from that of the first gate electrode, the step (a) includes the step of forming the third gate insulating film on the semiconductor region, the step (b) includes the step of forming a third gate silicon film on the third gate insulating film, the step (c) includes the step of forming a first sidewall spacer on a side of the third gate silicon film, the step (d) includes the step of forming a second sidewall spacer at the side of the third gate silicon film with the first sidewall spacer interposed therebetween, the step (e) includes the step of etching the first sidewall spacer such that the first sidewall spacer has an upper end lower than an upper surface of the third gate silicon film and an upper end of the second sidewall spacer, and the method further includes, after the step (e), the steps of: (i) forming another metal film on the third gate silicon film; and G) fully siliciding the third gate silicon film with said another metal film, thereby forming the third gate electrode.

Preferably, in the method, the semiconductor device further includes a resistor including a resistor element, the method further includes the step of (k) forming an isolation region in an upper portion of the semiconductor region before the step (a), the step (b) includes the step of forming a resistor silicon film on the isolation region, the step (c) includes the step of forming a first sidewall spacer on a side of the resistor silicon film, the step (d) includes the step of forming a second sidewall spacer at the side of the resistor silicon film with the first sidewall spacer interposed therebetween, the step (e) includes the step of etching the first sidewall spacer such that the first sidewall spacer has an upper end lower than an upper surface of the resistor silicon film and an upper end of the second sidewall spacer, the step (f) includes the step of forming the metal film on the resistor silicon film, and the step (g) includes the step of fully siliciding the resistor silicon film with the metal film, thereby forming the resistor element.

Preferably, in the method, the semiconductor device further includes a capacitor including an upper electrode, the step (a) includes the step of forming a capacitive insulating film on the semiconductor region, the step (b) includes the step of forming a capacitor silicon film on the capacitive insulating film, the step (c) includes the step of forming a first sidewall spacer on a side of the capacitor silicon film, the step (d) includes the step of forming a second sidewall spacer at the side of the capacitor silicon film with the first sidewall spacer interposed therebetween, the step (e) includes the step of etching the first sidewall spacer such that the first sidewall spacer has an upper end lower than an upper surface of the capacitor silicon film and an upper end of the second sidewall spacer, the step (f) includes the step of forming the metal film on the capacitor silicon film, and the step (g) includes the step of fully siliciding the capacitor silicon film with the metal film, thereby forming the upper electrode.

As described above, with a semiconductor device and a method for fabricating the device according to the present invention, a FUSI structure with a uniform gate-electrode composition, irrespective of the gate length of the gate electrode, so that variation of the threshold voltage is suppressed. In addition, variation of transistor characteristics caused by stress due to full silicidation is prevented.

### BRIEF DESCRIPTION OF THE DRAWINGS

FIG. 1 is a cross-sectional view schematically illustrating a semiconductor device according to a first embodiment of the present invention.

FIGS. 2A and 2B schematically illustrate a gate electrode in the semiconductor device of the first embodiment. FIG. 2A is a plan view and FIG. 2B is a cross-sectional view taken along the line IIb-IIb in FIG. 2A.

FIGS. 3A and 3B are cross-sectional views showing respective process steps of a method for fabricating a semiconductor device according to the first embodiment in the order of fabrication.

FIGS. 4A and 4B are cross-sectional views showing respective process steps of the method for fabricating a semiconductor device according to the first embodiment in the order of fabrication.

FIGS. 5A and 5B are cross-sectional views showing respective process steps of the method for fabricating a semiconductor device according to the first embodiment in the order of fabrication.

FIG. 6 is a cross-sectional view showing a process step of the method for fabricating a semiconductor device according to the first embodiment.

FIGS. 7A through 7C are cross-sectional views schematically illustrating a semiconductor device according to a second embodiment of the present invention.

FIGS. 8A through 8C are cross-sectional views showing respective process steps of a method for fabricating a semiconductor device according to the second embodiment in the order of fabrication.

FIGS. 9A through 9C are cross-sectional views showing respective process steps of the method for fabricating a semiconductor device according to the second embodiment in the order of fabrication.

FIGS. 10A through 10C are cross-sectional views showing respective process steps of the method for fabricating a semiconductor device according to the second embodiment in the order of fabrication.

FIGS. 11A through 11C are cross-sectional views showing respective process steps of the method for fabricating a semiconductor device according to the second embodiment in the order of fabrication.

FIGS. 12A through 12C are cross-sectional views showing respective process steps of the method for fabricating a semiconductor device according to the second embodiment in the order of fabrication.

FIGS. 13A through 13C are cross-sectional views showing respective process steps of the method for fabricating a semiconductor device according to the second embodiment in the order of fabrication.

FIGS. 14A through 14C are cross-sectional views schematically illustrating a semiconductor device according to a third embodiment of the present invention.

FIGS. 15A through 15C are cross-sectional views showing respective process steps of a method for fabricating a semiconductor device according to the third embodiment in the order of fabrication.

FIGS. 16A through 16C are cross-sectional views showing respective process steps of the method for fabricating a semiconductor device according to the third embodiment in the order of fabrication.

FIGS. 17A through 17C are cross-sectional views showing respective process steps of the method for fabricating a semiconductor device according to the third embodiment in the order of fabrication.

FIGS. 18A through 18C are cross-sectional views showing respective process steps of the method for fabricating a semiconductor device according to the third embodiment in the order of fabrication.

FIGS. 19A through 19C are cross-sectional views showing respective process steps of the method for fabricating a semiconductor device according to the third embodiment in the order of fabrication.

FIGS. 20A through 20C are cross-sectional views showing respective process steps of the method for fabricating a semiconductor device according to the third embodiment in the order of fabrication.

FIGS. 21A through 21C are cross-sectional views showing respective process steps of the method for fabricating a semiconductor device according to the third embodiment in the order of fabrication.

FIGS. 22A through 22C are cross-sectional views showing respective process steps of the method for fabricating a semiconductor device according to the third embodiment in the order of fabrication.

FIGS. 23A through 23D are cross-sectional views showing respective process steps of a method for fabricating a FET having a conventional FUSI electrode structure in the order of fabrication.

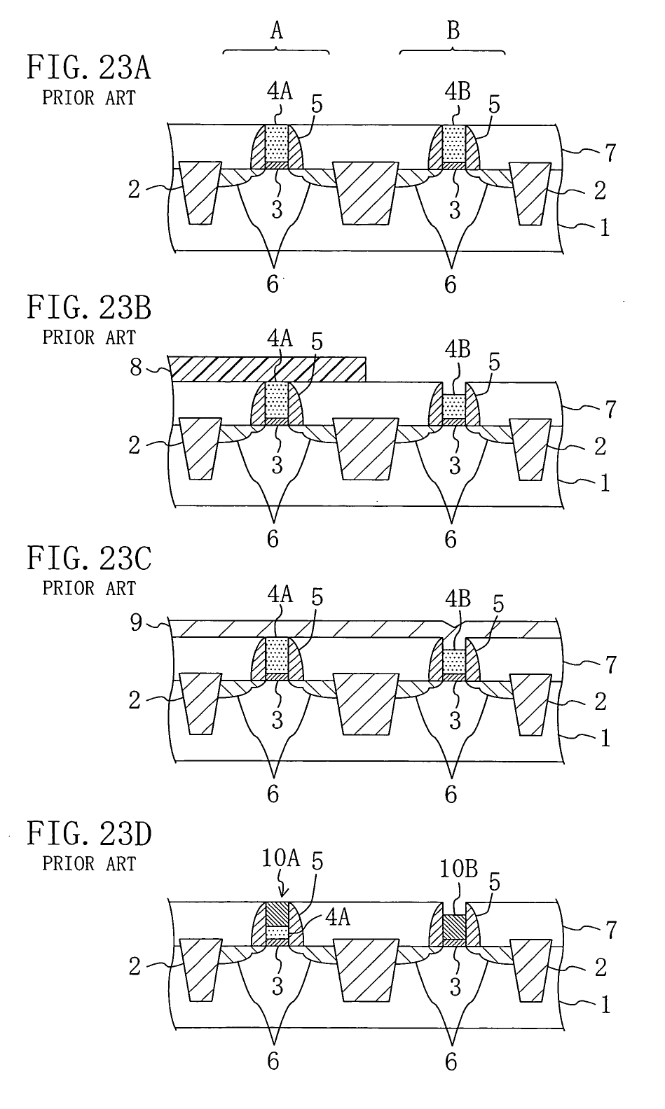

FIGS. 24A and 24B are cross-sectional views showing problems in the method for fabricating the FET having the conventional FUSI electrode structure in the order of fabrication.

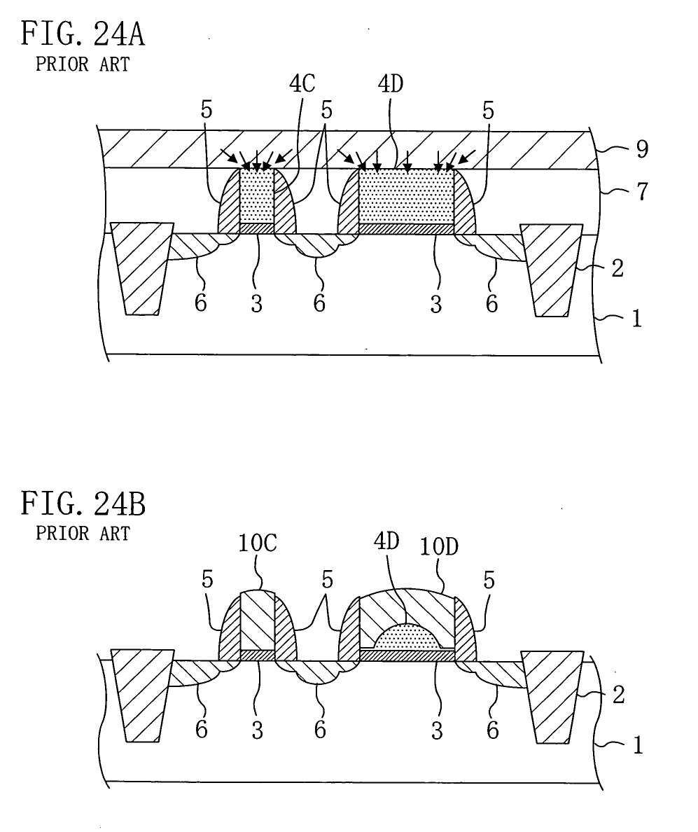

### DETAILED DESCRIPTION OF THE INVENTION

### Embodiment 1

A first embodiment of the present invention will be described with reference to the drawings.

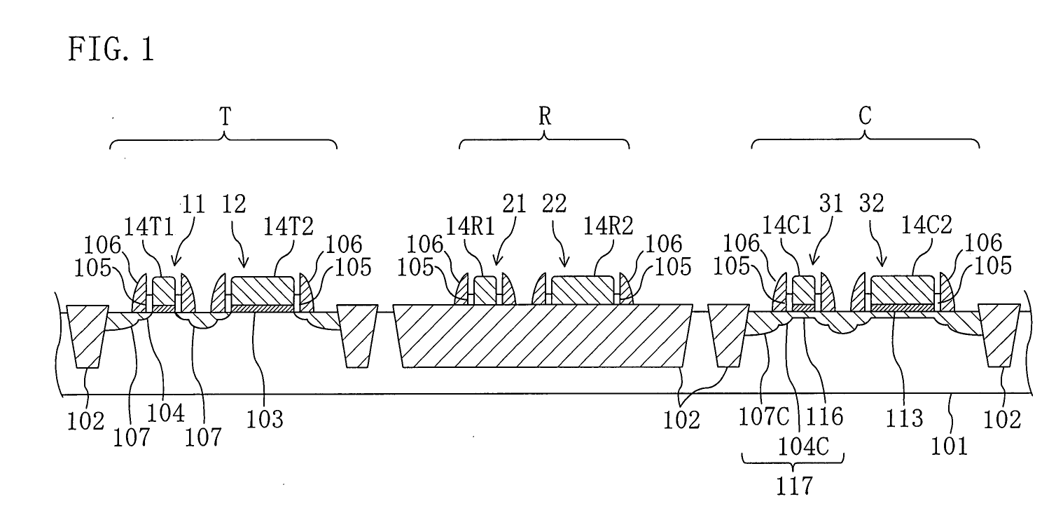

FIG. 1 illustrates a cross-sectional structure of a semiconductor device according to the first embodiment. As illustrated in FIG. 1, an FET region T, a resistor region R and a capacitor region C are defined by an isolation region 102 of shallow trench isolation (STI) in the principal surface of a semiconductor substrate 101 made of, for example, silicon (Si). In this embodiment, the resistor region R is provided on the isolation region 102.

In the FET region T, a first n-FET 11 and a second n-FET 12 having different gate lengths are formed. In the resistor region R, a first resistor 21 and a second resistor 22 having different widths are formed. In the capacitor region C, first and second capacitors 31 and 32 whose respective electrodes (upper electrodes) have different widths are formed.

Each of the first n-FET 11 and the second n-FET 12 in the FET region T includes: a gate insulating film 103 formed on the semiconductor substrate 101; a first gate electrode 14T1 formed on the gate insulating film 103 and made of fully-silicided (FUSI) metal silicide or a second gate electrode 14T2 formed on the gate insulating film 103, made of fully-silicided (FUSI) metal silicide and having a gate length larger than that of the first gate electrode 14T1; a first sidewall spacer 105 formed on both sides of the gate electrode 14T1 or 14T2 and made of, for example, silicon dioxide (SiO₂); a second sidewall spacer 106 formed on the first sidewall spacer 105 and made of silicon nitride (Si₃N₄); n-type extension regions 104 formed below the sides of the gate electrode 14T1 or 14T2 in the semiconductor substrate 101 and doped with n-type impurity ions; and n-type source/drain regions 107 formed below the sides of the second sidewall spacers 106 in the semiconductor substrate 101 and doped with n-type impurity ions.

Each of the first resistor 21 and the second resistor 22 in the resistor region R includes: a first resistor element 14R1 made of FUSI metal silicide or a second resistor element 14R2 made of FUSI metal silicide and having a width larger than that of the first resistor element 14R1; and a first sidewall spacer 105 and a second sidewall spacer 106 stacked on both sides of the resistor element 14R1 or 14R2.

Each of the first capacitor 31 and the second capacitor 32 in the capacitor region C is a MIS capacitor and includes: a capacitive insulating film 113 formed on the semiconductor substrate 101; a first upper electrode 14C1 formed on the capacitive insulating film 113 and made of FUSI metal silicide or a second upper electrode 14C2 formed on the capacitive insulating film 113, made of FUSI metal silicide and having a width larger than that of the first upper electrode 14C1; a first sidewall spacer 105 and a second sidewall spacer 106 stacked on both sides of the upper electrode 14C1 or 14C2; and a lower electrode 117 extending from a portion under the capacitive insulating film 113 to portions below the sides of the upper electrode 14C1 or 14C2 in the semiconductor substrate 101 and doped with n-type impurity ions. The lower electrode 117 includes: an n-type region 116 formed under the capacitive insulating film 113 in the semiconductor substrate 101 and doped with n-type impurity ions; n-type regions 104C formed below respective sides of the upper electrode 14C1 or 14C2 in the semiconductor substrate 101 and doped with n-type impurity ions; and n-type regions 107C formed below the sides of the second sidewall spacer 106 in the semiconductor substrate 101 and doped with n-type impurity ions.

The first embodiment is characterized in that the upper ends of the first sidewall spacers 105 on both sides, in the gate length direction, of the FUSI gate electrodes 14T1 and 14T2 are lower than the upper surfaces of the gate electrodes 14T1 and 14T2 and the upper ends of the second sidewall spacers 106. Likewise, the upper ends of the first sidewall spacers 105 on the sides of the FUSI resistor elements 14R1 and 14R2 and the FUSI upper electrodes 14C1 and 14C2 are lower than the upper surfaces of the resistor elements 14R1 and 14R2, the upper surfaces of the upper electrodes 14C1 and 14C2 and the upper ends of the associated second sidewall spacers 106.

In FIG. 1, the two FETs 11 and 12, the two resistors 21 and 22 and the two capacitors 31 and 32 are shown for convenience. However, a larger number of these components are actually formed on the semiconductor substrate 101.

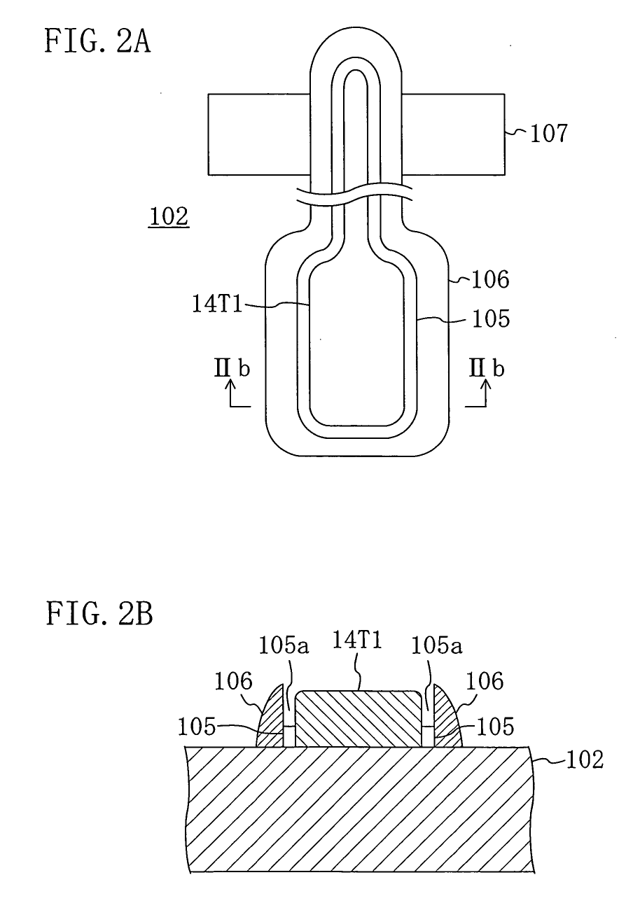

FIG. 2A illustrates a planar structure of the FUSI first gate electrode 14T1 of the semiconductor device of the first embodiment. FIG. 2B illustrates a cross-sectional structure taken along the line IIb-IIb in FIG. 2A. In FIGS. 2A and 2B, components also shown in FIG. 1 are denoted by the same reference numerals. A wide portion of the first gate electrode 14T1 in FIG. 2A is a contact portion formed on the isolation region 102. As illustrated in FIG. 2A, a first sidewall spacer 105 and a second sidewall spacer 106 are stacked around the first gate electrode 14T1 in this order. As illustrated in FIG. 2B, a gap 105a sandwiched between the first gate electrode 14T1 and the second sidewall spacer 106 is formed above the first sidewall spacer 105. In this embodiment, description is given on the first gate electrode 14T1 of the n-FET as an example. However, the first and second resistor elements 14R1 and 14R2 of the resistors 21 and 22 and the first and second upper electrodes 14C1 and 14C2 of the capacitors 31 and 32 as well as the second gate electrode 14T2 have the same structure.

In the semiconductor device of the first embodiment with the foregoing structure, the FUSI gate electrodes 14T1 and 14T2 with the same structure, the FUSI resistor elements 14R1 and 14R2 with the same structure and the FUSI upper electrodes 14C1 and 14C2 with the same structure have the same composition in a self-aligned manner, irrespective of the sizes (i.e., planar dimensions) of the gate electrodes 14T1 and 14T2, the resistor elements 14R1 and 14R2 and the upper electrodes 14C1 and 14C2, respectively. Accordingly, in the n-FETs 11 and 12, for example, variation of the threshold voltage due to nonuniformity of the composition depending on the sizes of the first and second gate electrodes 14T1 and 14T2 is prevented. In addition, variations of the resistance values are also prevented in the resistors 21 and 22, and variations of the capacitance values are also prevented in the capacitors. As a result, performance of the semiconductor device is enhanced and integration degree is increased.

In FIG. 1, the first n-FET 11 and the second n-FET 12 are formed on the same region of the semiconductor substrate 101 defined by the isolation region 102, the first capacitor 31 and the second capacitor 32 are also formed on the same region of the semiconductor substrate 101 defined by the isolation region 102, as an example. These components may be individually formed in respective regions defined by the isolation region 102. Alternatively, two types of the components may be formed in the same region in combination. In this embodiment, the first resistor 21 and the second resistor 22 are formed to be adjacent to each other on the isolation region 102. Alternatively, the resistors 21 and 22 may be formed on separate isolation regions 102. The n-FETs 11 and 12 may be p-FETs. The devices to be formed are not limited to FETs, resistors and capacitors, and may be other devices using conductors with FUSI structures, e.g., fuses.

Hereinafter, a method for fabricating a semiconductor device configured as described above will be described with reference to the drawings.

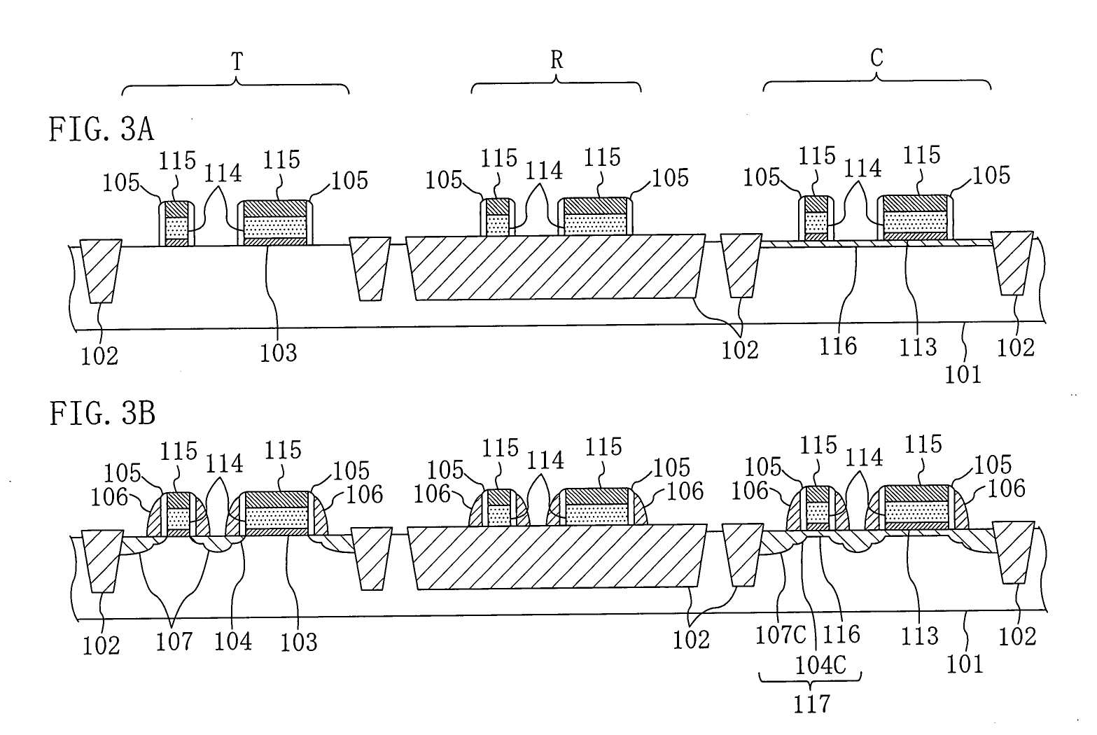

FIGS. 3A and 3B through FIG. 6 illustrate cross-sectional structures in respective process steps of a method for fabricating a semiconductor device according to the first embodiment in the order of fabrication.

First, as illustrated in FIG. 3A, an isolation region 102 of STI is formed in an upper portion of a semiconductor substrate 101 made of silicon. Thereafter, n-type impurity ions, for example, are selectively implanted in a capacitor region C, thereby forming an n-type region 116 to be a pair of a lower electrode 117 in an upper portion of the semiconductor substrate 101. This n-type region 116 is to be a lower electrode 117 directly under a capacitive insulating film 113. Then, a gate insulating film 103 and a capacitive insulating film 113 are deposited by chemical vapor deposition (CVD) to have a physical thickness of 3 nm over an FET region T and a capacitor region C, respectively, of the principal surface of the semiconductor substrate 101. At this time, an insulating film made of hafnium oxide may be formed on the isolation region 102 in the resistor region R. Subsequently, a conductive polysilicon film 114 with a thickness of 75 nm and a protective insulating film 115 of silicon dioxide (SiO₂) with a thickness of 25 nm are deposited in this order by CVD over the semiconductor substrate 101 with the gate insulating film 103 interposed between the polysilicon film 114 and the semiconductor substrate 101 in the FET region T and the capacitive insulating film 113 interposed between the polysilicon film 114 and the semiconductor substrate 101 in the capacitor region C. The polysilicon film 114 may be made of conductive amorphous silicon. Thereafter, a resist pattern (not shown) masking a gate-electrode region of the FET region T, a resistor-element region of the resistor region R and an upper-electrode region of the capacitor region C is formed on the protective insulating film 115 by lithography. Subsequently, patterning is performed on the protective insulating film 115 and the polysilicon film 114 by etching using the resist pattern as a mask, thereby forming first and second gate-electrode patterns having different gate lengths in the FET region T, forming first and second resistor-element patterns having different widths in the resistor region R, and forming first and second upper-electrode patterns having different widths in the capacitor region C. For this etching, if dry etching is adopted, an etching gas containing fluorocarbon as a main component is used for silicon dioxide and an etching gas containing chlorine as a main component is used for polysilicon, for example. Subsequently, a silicon dioxide film is deposited by CVD to a thickness of 5 nm over the semiconductor substrate 101 to cover the polysilicon film 114 and the protective insulating film 115 obtained by patterning. Then, the deposited silicon dioxide film is etched back, thereby forming a first sidewall spacer 105 of silicon dioxide on both faces of each of the gate-electrode patterns, the resistor-element patterns and the upper-electrode patterns.

Next, as illustrated in FIG. 3B, n-type impurity ions are implanted in the semiconductor substrate 101 using the protective insulating film 115 as a mask, thereby forming n-type extension regions 104 in the FET region T and forming n-type regions 104C to be a part of a lower electrode 117 in the capacitor region C. Thereafter, a silicon nitride film, for example, is deposited by CVD over the semiconductor substrate 101 to cover the polysilicon film 114 and the protective insulating film 115 provided with the first sidewall spacers 105 and then is etched back, thereby forming second sidewall spacers 106 at both sides of the polysilicon film 114 and the protective insulating film 115 with the first sidewall spacers 105 interposed between the second sidewall spacers 106 and the films. Subsequently, n-type impurity ions are implanted in the semiconductor substrate 101 using the protective insulating film 115, the first sidewall spacers 105 and the second sidewall spacers 106 as masks, thereby forming n-type source/drain regions 107 in the FET region T and forming n-type regions 107C to be a part of the lower electrode 117 in the capacitor region C. In this manner, source/drain regions made of the n-type extension regions 104 and the n-type source/drain regions 107 are formed in the FET region T and the lower electrodes 117 made of the n-type regions 104C, the n-type regions 107C and the n-type regions 116 are formed in the resistor region C. Thereafter, the surfaces of the n-type source/drain regions 107 and the n-type regions 107C in the lower electrodes 117 may be silicided with, for example, nickel (Ni). In this embodiment, the first sidewall spacers 105 are formed only on the sides of the gate insulating film 103, the polysilicon film 114 and the protective insulating film 115. Alternatively, each of the first sidewall spacers 105 may have an L-shape in cross section such that a lower portion of the first sidewall spacer 105 extends to be sandwiched between the bottom of the associated second sidewall spacer 106 and the semiconductor substrate 101. The second sidewall spacers 106 are not only necessarily made of silicon nitride, and may have a double-layer structure made of silicon oxide and silicon nitride or a triple-layer structure made of silicon oxide, silicon nitride and silicon oxide.

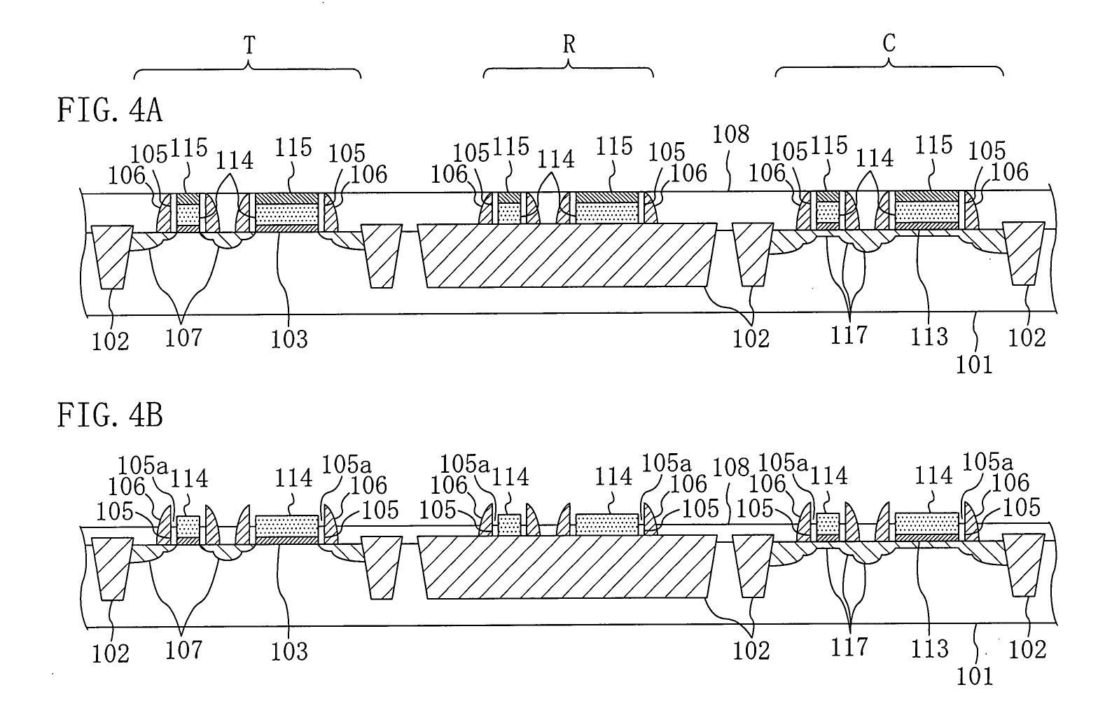

Then, as illustrated in FIG. 4A, an interlayer insulating film 108 made of, for example, silicon dioxide is deposited by CVD over the semiconductor substrate 101 to cover the protective insulating film 115 and the sidewall spacers 105 and 106, and then is planarized by, for example, chemical mechanical polishing (CMP), thereby exposing the upper surface of the protective insulating film 115.

Thereafter, as illustrated in FIG. 4B, the protective insulating film 115 is removed by, for example, wet etching, thereby exposing the polysilicon film 114 underlying the protective insulating film 115. At this time, since both the first sidewall spacers 105 and the protective insulating film 115 are made of silicon dioxide, etching is performed such that the upper ends of the resultant first sidewall spacers 105 are lower than the upper surfaces of the adjacent portions of the polysilicon film 114. At this time, the distance (i.e., the depth of gaps 105a) from the upper surface of the polysilicon film 114 to the upper ends of the first sidewall spacers 105 is preferably equal to or larger than the width of the first sidewall spacers 105. In the first embodiment, since the interlayer insulating film 108 is made of silicon dioxide, the interlayer insulating film 108 is etched simultaneously with etching of the protective insulating film 115 and the first sidewall spacers 105. However, even when the interlayer insulating film 108 is etched at the same time, the etching is allowed to be controlled so as not to expose the semiconductor substrate 101, thus causing no substantial problems. For the protective insulating film 115 and the interlayer insulating film 108, materials or deposition conditions having different etch rates may be used. For example, if phosphorus (P) or boron (B) is added to silicon dioxide forming the protective insulating film 115, the etch rate of the protective insulating film 115 is higher than that of the interlayer insulating film 108, so that the selectivity with respect to the interlayer insulating film 108 is obtained. To provide silicon nitride forming the polysilicon film 114 and the second sidewall spacers 106 with selectivity with respect to silicon dioxide, an etchant containing hydrogen fluoride as a main component may be used in the case of wet etching. On the other hand, in the case of dry etching, reactive ion etching may be used under conditions in which C₅F₈ at a flow rate of 15 ml/min (standard condition, i.e., 0° C., 1 atm), O₂ at a flow rate of 18 ml/min (standard condition) and Ar at a flow rate of 950 ml/min (standard condition) are supplied under a pressure of 6.7 Pa with an RF power (T/B) is 1800W/1500W at a substrate temperature of 0° C., for example. In this manner, gaps 105a having a high aspect ratio are formed between the second sidewall spacers 106 and the polysilicon film 114. In the first embodiment, the protective insulating film 115 is previously deposited on the polysilicon film 114, and then upper portions of the respective first sidewall spacers 105 are etched simultaneously with removal of the protective insulating film 115 by etching. Alternatively, the protective insulating film 115 and the first sidewall spacers 105 may be made of different materials so that the protective insulating film 115 and the first sidewall spacers 105 are individually etched in separate processes. The interlayer insulating film 108 may also be deposited directly on the polysilicon film 114 with no protective insulating film 115 deposited so that upper portions of the respective first sidewall spacers 105 are removed by etching after exposure of the upper surfaces of the polysilicon film 114 by, for example, CMP.

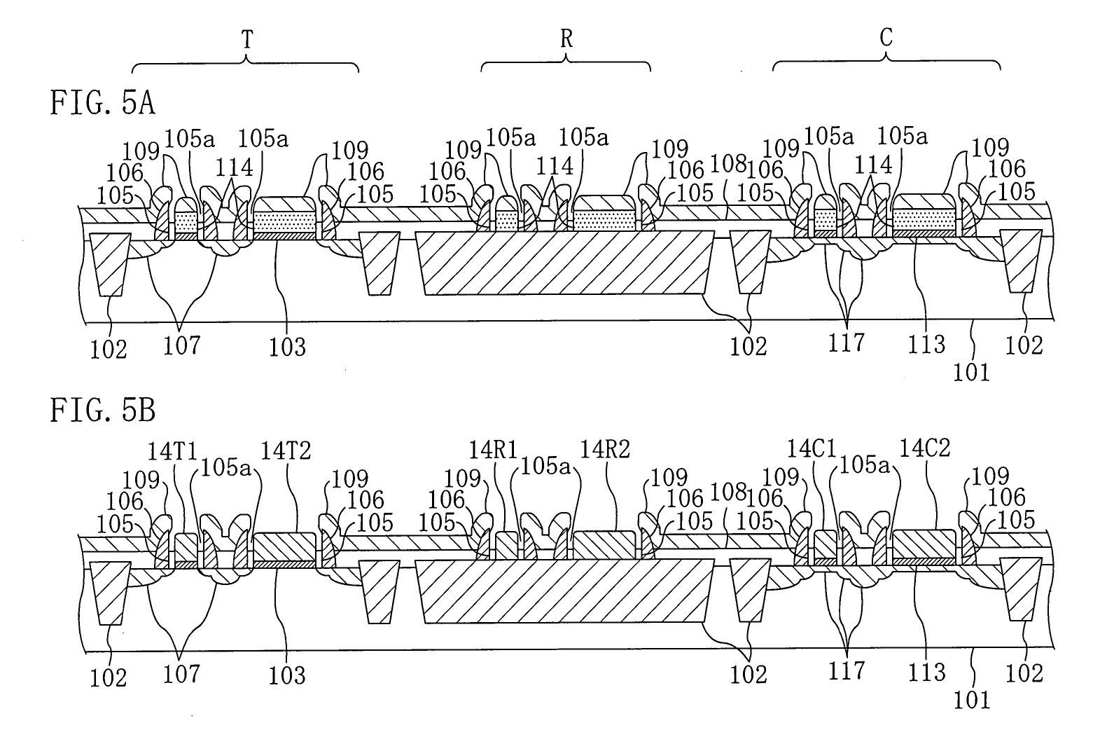

Then, as illustrated in FIG. 5A, a metal film 109 made of nickel (Ni) is deposited by sputtering to a thickness of, for example, 45 nm over the interlayer insulating film 108 including the exposed sidewall spacers 105 and 106 and the exposed polysilicon film 114. The deposition of the metal film 109 generally has poor step coverage, i.e., high directivity, so that substantially no metal film 109 is deposited in gaps 105a on the first sidewall spacers 105 between the second sidewall spacers 106 and the polysilicon film 114, irrespective of the size of the polysilicon film 114. Accordingly, the gaps 105a remain. It should be noted that the metal film 109 is deposited across the gaps 105a in some cases. However, in such cases, the thickness of the metal film 109 is small, and no substantial problem occurs.

Thereafter, as illustrated in FIG. 5B, heat treatment is performed on the semiconductor substrate 101 by, for example, rapid thermal annealing (RTA) at 400° C. in a nitrogen atmosphere to cause silicidation between the polysilicon film 114 and the metal film 109, thereby siliciding the entire polysilicon film 114. Then, a first gate electrode 14T1 and a second gate electrode 14T2 both having FUSI structures and having different gate lengths are formed on the FET region T of the semiconductor substrate 101, a first resistor element 14R1 and a second resistor element 14R2 both having FUSI structures and having different widths are formed on the resistor region R, and a first upper electrode 14C1 and a second upper electrode 14C2 both having FUSI structures and having different widths are formed on the capacitor region C.

The first embodiment is characterized in that the gaps 105a are formed by removing upper portions of the first sidewall spacers 105 between the second sidewall spacers 106 and the polysilicon film 114 so that portions of the metal film 109 are isolated from each other on the polysilicon film 114 or portions of the metal film 109 across the gaps 105a are thinner than the other portions. This prevents metal for silicidation from being excessively supplied to the polysilicon film 114 from portions over the second sidewall spacers 106 and their neighboring portions. Accordingly, the volume ratio between portions of the polysilicon film 114 capable of reacting and portions of the metal film 109 capable of reacting does not depend on the gate lengths, i.e., the planar dimensions, of, for example, the gate electrodes 14T1 and 14T2. Specifically, the volume ratio between the reactable portions of the polysilicon film 114 and the reactable portions of the metal film 109 is determined by the thickness of the polysilicon film 114 exposed in the process step shown in FIG. 4B and the thickness of the metal film 109 deposited in the process step shown in FIG. 5A, and is substantially uniform. In other words, silicidation in the polysilicon film 114 transitions from reaction-limited to supply-limited. In this manner, even the gate electrodes 14T1 and 14T2, the resistor elements 14R1 and 14R2 and the upper electrodes 14C1 and 14C2 having different planar dimensions are allowed to have FUSI structures with uniform compositions. Since silicidation occurs between the polysilicon film 114 and its overlying the metal film 109, substantially no growth occurs in the lateral direction (i.e., the in-plane direction of the semiconductor substrate 101). Accordingly, upper portions of the FUSI gate electrodes 14T1 and 14T2 are isolated between the second sidewall spacers 106, and the gaps 105a are maintained. In addition, no silicidation occurs in portions of the metal film 109 deposited over the n-type source/drain regions 107 and the lower electrodes 117 because the interlayer insulating film 108 is interposed therebetween.

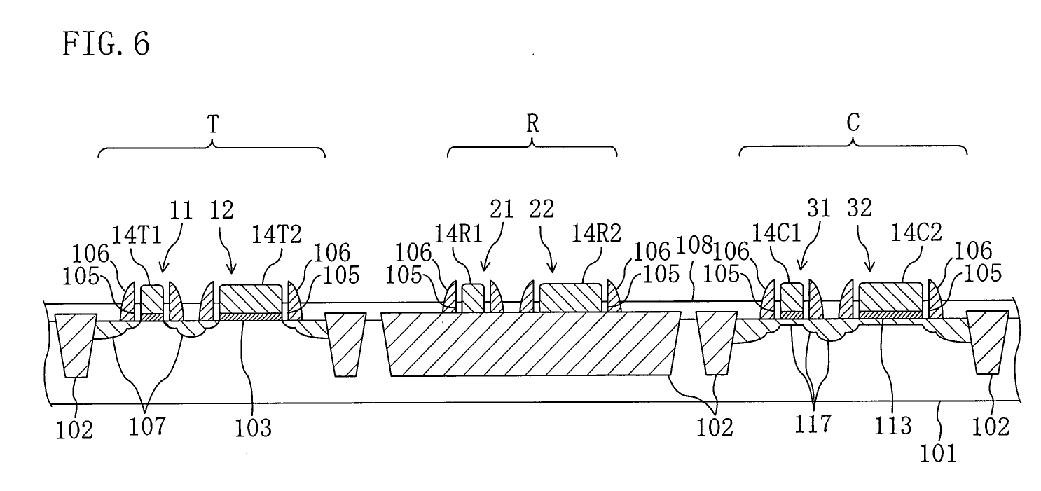

Then, as illustrated in FIG. 6, the unreacted portions of the metal film 109 remaining on the interlayer insulating film 108 and other components are removed by etching using a solution in which hydrochloric acid and a hydrogen peroxide solution, for example, are mixed. Thereafter, an upper-level interlayer insulating film is deposited over the interlayer insulating film 108 including the FUSI gate electrodes 14T1 and 14T2 and other components, thereby forming contact holes and interconnections.

As described above, with the method for fabricating a semiconductor device according to the first embodiment, the first sidewall spacers 105 and the second sidewall spacers 106 are stacked on the sides of the polysilicon film 114 to be silicided, and then upper portions of the first sidewall spacers 105 are removed, thereby forming the gaps 105a between the second sidewall spacers 106 and the polysilicon film 114. In this manner, in depositing the metal film 109 on the polysilicon film 114, portions of the metal film 109 are isolated from each other on the polysilicon film 114. Even if the portions of the metal film 109 are not isolated, the thickness of portions of the metal film 109 across the gaps 105a is smaller than that of the other portions. Accordingly, it is possible to prevent metal from being excessively supplied from portions of the metal film 109 over the interlayer insulating film 108 and the second sidewall spacers 106 to the polysilicon film 114. As a result, the gate electrodes 14T1 and 14T2, the resistor elements 14R1 and 14R2 and the upper electrodes 14C1 and 14C2 have uniform FUSI structures with the same composition, irrespective of the size.

In a conventional method, stress due to the difference in expansion or shrinkage coefficient between a gate electrode and a sidewall spacer is applied to the semiconductor substrate with a sidewall spacer interposed therebetween. However, in this embodiment, the gaps 105a formed on the sides of the gate electrodes 14T1 and 14T2 greatly reduce the stress applied on the semiconductor substrate 101 from the gate electrodes 14T1 and 14T2 with the second sidewall spacers 106 interposed therebetween, irrespective of the planar dimensions of the gate electrodes 14T1 and 14T2. Accordingly, variation of transistor characteristics caused by the stress due to full silicidation is prevented.

In the method of the first embodiment, the first n-FET 11, the second n-FET 12, the first resistor 21, the second resistor 22, the first capacitor 31 and the second capacitor 32 having the same uniform FUSI structure are formed at a time on the single semiconductor substrate 101.

The n-FETs 11 and 21 are formed in the FET region T, but p-FETs may be formed instead.

The gate insulating film 103 and the capacitive insulating film 113 are made of hafnium oxide (HfO₂), but may be made of HfSiO, HfSiON, SiO₂ or SiON, for example. In this embodiment, the gate insulating film 103 and the capacitive insulating film 113 are formed in the same process step, but may be formed in different process steps.

In the first embodiment, in the process step shown in FIG. 4A, the protective insulating film 115 is exposed from the planarized interlayer insulating film 108, and then the protective insulating film 115 and the first sidewall spacers 105 are etched. However, the present invention is not limited to this, and the protective insulating film 115 and the first sidewall spacers 105 may be etched with no interlayer insulating film 108 formed.

### Embodiment 2

Hereinafter a second embodiment of the present invention will be described with reference to the drawings.

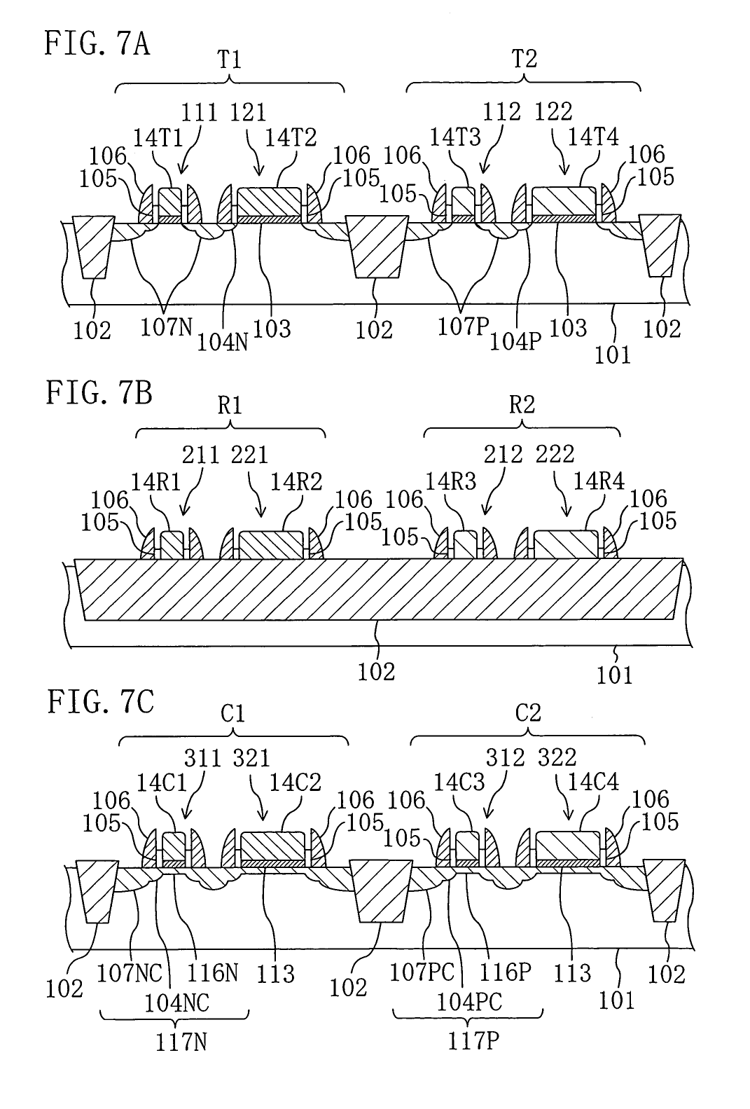

FIGS. 7A through 7C illustrate a cross-sectional structure of a semiconductor device according to the second embodiment. In FIGS. 7A through 7C, components also shown in FIG. 1 are denoted by the same reference numerals and description thereof will be omitted. The semiconductor device of this embodiment are partitioned into portions illustrated in FIGS. 7A through 7C for convenience, but is actually formed on one semiconductor substrate 101.

As illustrated in FIGS. 7A through 7C, the semiconductor device of the second embodiment includes: an n-FET region T1; a p-FET region T2; a first resistor region R1; a second resistor region R2; a first capacitor region C1; and a second capacitor region C2, as a plurality of device regions defined by an isolation region 102 selectively formed in an upper portion of the semiconductor substrate 101. In this embodiment, the resistor regions R1 and R2 are formed on the isolation region 102.

As illustrated in FIG. 7A, a first n-FET 111 and a second n-FET 121 having different gate lengths are formed in the n-FET region T1. A first p-FET 112 and a second p-FET 122 having different gate lengths are formed in the p-FET region T2.

As illustrated in FIG. 7B, a first resistor 211 and a second resistor 221 having different widths are formed in the first resistor region R1, and a third resistor 212 and a fourth resistor 222 having different widths are formed in the second resistor region R2.

As illustrated in FIG. 7C, a first capacitor 311 and a second capacitor 321 having different widths are formed in the first capacitor region C1. A third capacitor 312 and a fourth capacitor 322 having different widths are formed in the second capacitor region C2.

Each of the first n-FET 111 and the second n-FET 121 in the n-FET region T1 includes: a gate insulating film 103 formed on the semiconductor substrate 101; a first gate electrode 14T1 formed on the gate insulating film 103 and made of FUSI NiSi or a second gate electrode 14T2 formed on the gate insulating film 103, made of FUSI NiSi and having a gate length larger than that of the first gate electrode 14T1; a first sidewall spacer 105 formed on both sides of the gate electrode 14T1 or 14T2; a second sidewall spacer 106 formed on the first sidewall spacer 105; n-type extension regions 104N formed below the sides of the gate electrode 14T1 or 14T2 in the semiconductor substrate 101; and n-type source/drain regions 107N formed below the sides of the second sidewall spacer 106 in the semiconductor substrate 101.

Each of the first p-FET 112 and the second p-FET 122 in the p-FET region T2 includes: a gate insulating film 103 formed on the semiconductor substrate 101; a third gate electrode 14T3 formed on the gate insulating film 103 and made of FUSI Ni₃Si or a fourth gate electrode 14T4 formed on the gate insulating film 103, made of FUSI Ni₃Si and having a gate length larger than that of the third gate electrode 14T3; a first sidewall spacer 105 formed on both sides of the gate electrode 14T3 or 14T4; a second sidewall spacer 106 formed on the first sidewall spacer 105; and p-type extension regions 104P formed below the sides of the gate electrode 14T3 or 14T4 in the semiconductor substrate 101; and the p-type source/drain regions 107P formed below the sides of the second sidewall spacers 106 in the semiconductor substrate 101.

Each of the first resistor 211 and the second resistor 221 in the first resistor region R1 includes: a first resistor element 14R1 made of FUSI NiSi or a second resistor element 14R2 made of FUSI NiSi and having a width larger than that of the first resistor element 14R1; and a first sidewall spacer 105 and a second sidewall spacer 106 stacked on both sides of the resistor element 14R1 or 14R2.

Each of the third resistor 212 and the fourth resistor 222 in the second resistor region R2 includes: a third resistor element 14R3 made of FUSI Ni₃Si or a fourth resistor element 14R4 made of FUSI Ni₃Si and having a width larger than that of the third resistor element 14R3; and a first sidewall spacer 105 and a second sidewall spacer 106 stacked on both sides of the resistor element 14R3 or 14R4.

Each of the first capacitor 311 and the second capacitor 321 in the first capacitor region C1 is a MIS capacitor, and includes: a capacitive insulating film 113 formed on the semiconductor substrate 101; a first upper electrode 14C1 formed on the capacitive insulating film 113 and made of FUSI NiSi or a second upper electrode 14C2 formed on the capacitive insulating film 113, made of FUSI NiSi and having a width larger than that of the first upper electrode 14C1; a first sidewall spacer 105 formed on both sides of the upper electrode 14C1 or 14C2; a second sidewall spacer 106 formed on the first sidewall spacer 105; and an n-type lower electrode 117N extending from a portion under the capacitive insulating film 113 to portions below the sides of the upper electrode 14C1 or 14C2 in the semiconductor substrate 101 and doped with n-type impurity ions. The n-type lower electrode 117N includes: an n-type region 116N formed under the capacitive insulating film 113 in the semiconductor substrate 101 and doped with n-type impurity ions; n-type regions 104NC formed below the sides of the upper electrode 14C1 or 14C2 in the semiconductor substrate 101 and doped with n-type impurity ions; and n-type regions 107NC formed below the sides of the second sidewall spacer 106 in the semiconductor substrate 101 and doped with n-type impurity ions.

Each of the third capacitor 312 and the fourth capacitor 322 in the second capacitor region C2 is a MIS capacitor, and includes: a capacitive insulating film 113 formed on the semiconductor substrate 101; a third upper electrode 14C3 formed on the capacitive insulating film 113 and made of FUSI Ni₃Si or a fourth upper electrode 14C4 formed on the capacitive insulating film 113, made of FUSI Ni₃Si and having a width larger than that of the third upper electrode 14C3; a first sidewall spacer 105 formed on both sides of the upper electrode 14C3 or 14C4; a second sidewall spacer 106 formed on the first sidewall spacer 105; and a p-type lower electrode 117P extending from a portion under the capacitive insulating film 113 to portions below the sides of the upper electrode 14C3 or 14C4 in the semiconductor substrate 101 and doped with p-type impurity ions. The p-type lower electrode 117P includes: a p-type region 116P formed under the capacitive insulating film 113 in the semiconductor substrate 101 and doped with p-type impurity ions; p-type regions 104PC formed below the sides of the upper electrode 14C3 or 14C4 in the semiconductor substrate 101 and doped with p-type impurity ions; and p-type regions 107PC formed below the second sidewall spacer 106 in the semiconductor substrate 101 and doped with p-type impurity ions.

In this manner, in the semiconductor device of the second embodiment, the composition of nickel silicide (Ni composition) differs between the first and second gate electrodes 14T1 and 14T2 and between the third and fourth gate electrodes 14T3 and 14T4 in the n-FET region T1 and the p-FET region T2, respectively. In the same manner, the composition of nickel silicide (Ni composition) also differs between the first and second resistor elements 14R1 and 14R2, between the third and fourth resistor elements 14R3 and 14R4, between the first and second upper electrodes 14C1 and 14C2 and between the third and fourth upper electrodes 14C3 and 14C4. In addition, with respect to the first sidewall spacers 105 and the second sidewall spacers 106 on the sides of the FUSI gate electrodes 14T1 through 14T4, the FUSI resistor elements 14R1 through 14R4 and the FUSI upper electrodes 14C1 through 14C4, the upper ends of the first sidewall spacers 105 are lower than the upper surfaces of the gate electrodes 14T1 through 14T4, the resistor elements 14R1 through 14R4 and the upper electrodes 14C1 through 14C4 and the upper ends of the second sidewall spacers 106.

With this structure, in the semiconductor device of the second embodiment, the n-FET region T1, the first resistor region R1 and the first capacitor region C1 have the same composition, irrespective of the sizes (planar dimensions) of the FUSI structures. The p-FET region T2, the second resistor region R2 and the second capacitor region C2 also have the same composition, irrespective of the sizes (planar dimensions) of the FUSI structures. Accordingly, in the FETs, variations of the threshold voltages due to composition nonuniformity depending on the sizes of the gate electrodes are prevented. As a result, performance of the semiconductor device is enhanced and integration degree is increased.

In the resistors 211 through 222 and the capacitors 311 through 322, variations of the resistance value and the capacitance value are prevented.

In FIGS. 7A through 7C, each pair of the n-FETs 111 and 121, the p-FETs 112 and 122, the capacitors 311 and 321, and the capacitors 312 and 322 are formed in the same region of the semiconductor substrate 101 defined by the isolation region 102, as an example. However, these devices may be individually formed in different regions defined by the isolation region 102, or two types of these components may be formed in the same region in combination. The resistors 211, 221, 212 and 222 are formed to be adjacent to each other on the isolation region 102. Alternatively, the resistors may be formed on respective separate isolation regions 102. The FETs do not necessarily have two gate lengths and may have three or more gate lengths.

In this embodiment, two types of materials, i.e., NiSi and Ni₃Si, are used for the gate electrodes 14T1 and 14T3 and the resistor elements 14R1 and 14R3, for example, but three or more types of materials may be used.

For the FETs, irrespective of the sizes (gate lengths) of the gate electrodes, stress on the semiconductor substrate 101 due to the difference in expansion coefficient between the silicide material and the second sidewall spacers 106 during heat treatment after full silicidation is reduced by the gaps 105a above the first sidewall spacers 105, thereby preventing variation in FET characteristics due to stress difference.

In the second embodiment, the FETs, the resistors and the capacitors are used as exemplary components, but the present invention is applicable to other devices using conductors with FUSI structures, e.g., fuses.

Hereinafter, a method for fabricating a semiconductor device configured as described above will be described with reference to the drawings.

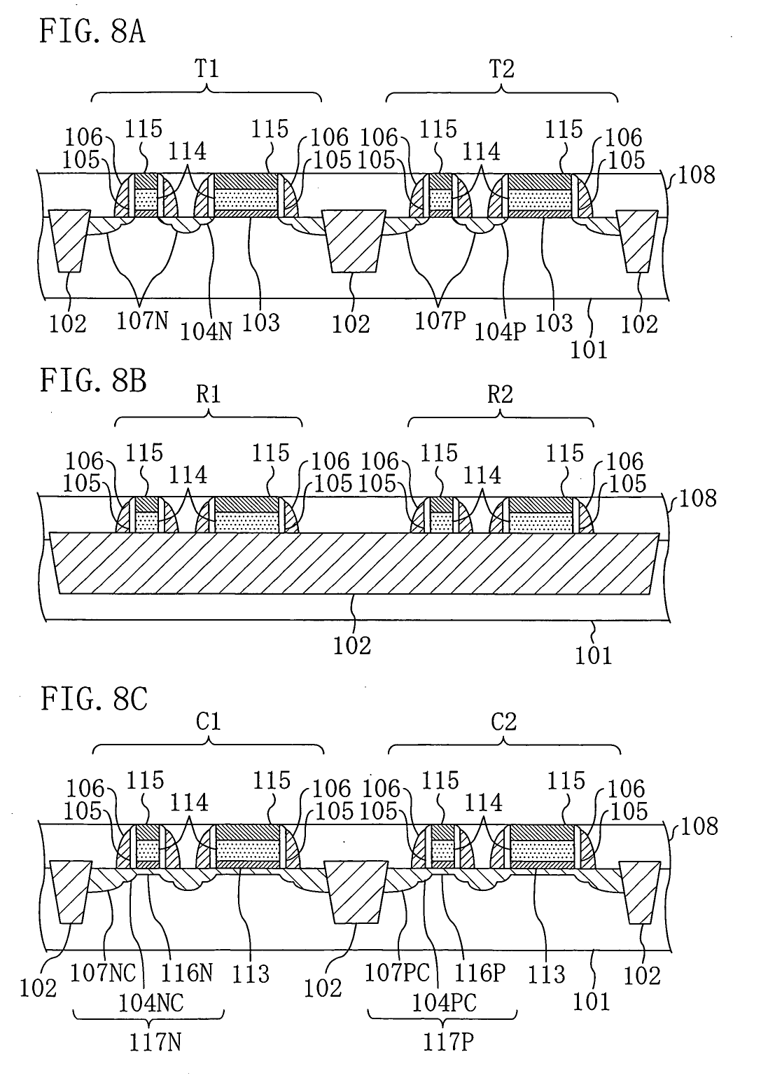

FIGS. 8A through 8C to FIGS. 13A through 13C illustrate cross-sectional structures in respective process steps of a method for fabricating a semiconductor device according to the second embodiment.

First, as illustrated in FIGS. 8A through 8C, as in the first embodiment, an isolation region 102 is selectively formed in an upper portion of a semiconductor substrate 101 made of silicon. Subsequently, an n-type impurity is selectively implanted in a first capacitor region C1 of the semiconductor substrate 101, thereby forming n-type regions 116N to be parts of respective n-type lower electrodes 117N. A p-type impurity is selectively implanted in a second capacitor region C2 of the semiconductor substrate 101, thereby forming p-type regions 116P to be parts of respective p-type lower electrodes 117P. Thereafter, a gate insulating film 103 and a capacitive insulating film 113 both made of, for example, HfO₂ are deposited by CVD over the principal surface of the semiconductor substrate 101. At this time, an insulating film made of hafnium oxide may be formed on the gate insulating film 102 in a resistor region R. Subsequently, a polysilicon film 114 having a thickness of 75 nm and a protective insulating film 115 having a thickness of 25 nm and made of silicon oxide are deposited in this order by CVD over the semiconductor substrate 101 with the gate insulating film 103 interposed between the polysilicon film 114 and the semiconductor substrate 101 in the n-FET region T1 and the p-FET region T2 and with the capacitive insulating film 113 interposed between the polysilicon film 114 and the semiconductor substrate 101 in the first capacitor region C1 and the second capacitor region C2. Thereafter, the protective insulating film 115 and the polysilicon film 114 are patterned by lithography and etching, thereby forming first and second gate-electrode patterns having different gate lengths and forming third and fourth gate-electrode patterns having different gate lengths in the n- and p-FET regions T1 and T2. In the first and second resistor regions R1 and R2, first and second resistor patterns having different widths and third and fourth resistor patterns having different widths are formed. In the first and second capacitor regions C1 and C2, first and second upper-electrode patterns having different widths and third and fourth upper-electrode patterns having different widths are formed. Then, first sidewall spacers 105 having a thickness of 5 nm and made of silicon oxide are formed by CVD on both sides of each of the polysilicon film 114 and the protective insulating film 115 formed by patterning. Subsequently, using the first sidewall spacers 105 and the protective insulating film 115 as masks, n-type extension regions 104N and n-type regions 104NC to be parts of the respective n-type lower electrodes 117N are formed in the n-FET region T1 and the first capacitor region C1, respectively. Thereafter, p-type extension regions 104P and p-type regions 104PC to be parts of the respective p-type lower electrodes 117P are formed in the p-FET region T2 and the second capacitor region C2, respectively. The order of the step of implanting n-type impurity ions and the step of implanting p-type impurity ions is not limited. Subsequently, second sidewall spacers 106 of silicon nitride are formed at both sides of each of the polysilicon film 114 and the protective insulating film 115 with the first sidewall spacers 105 interposed therebetween. Thereafter, using the protective insulating film 115, the first sidewall spacers 105 and the second sidewall spacers 106 as masks, n-type source/drain regions 107N and n-type regions 107NC to be parts of the respective n-type lower electrodes 117N are formed. Then, p-type source/drain regions 107P and p-type regions 107PC to be parts of the respective p-type lower electrodes 117P are formed. Thereafter, the exposed surfaces of the n-type source/drain regions 107N, the p-type source/drain regions 107P, the n-type regions 107NC in the lower electrodes 117 and the p-type regions 107PC in the p-type lower electrodes 117P may be silicided with nickel (Ni), for example. Then, an interlayer insulating film 108 made of silicon oxide is deposited by CVD over the semiconductor substrate 101 to cover the protective insulating film 115 and the sidewall spacers 105. Then, the upper surface of the interlayer insulating film 108 is planarized by CMP, thereby exposing the upper surface of the protective insulating film 115.

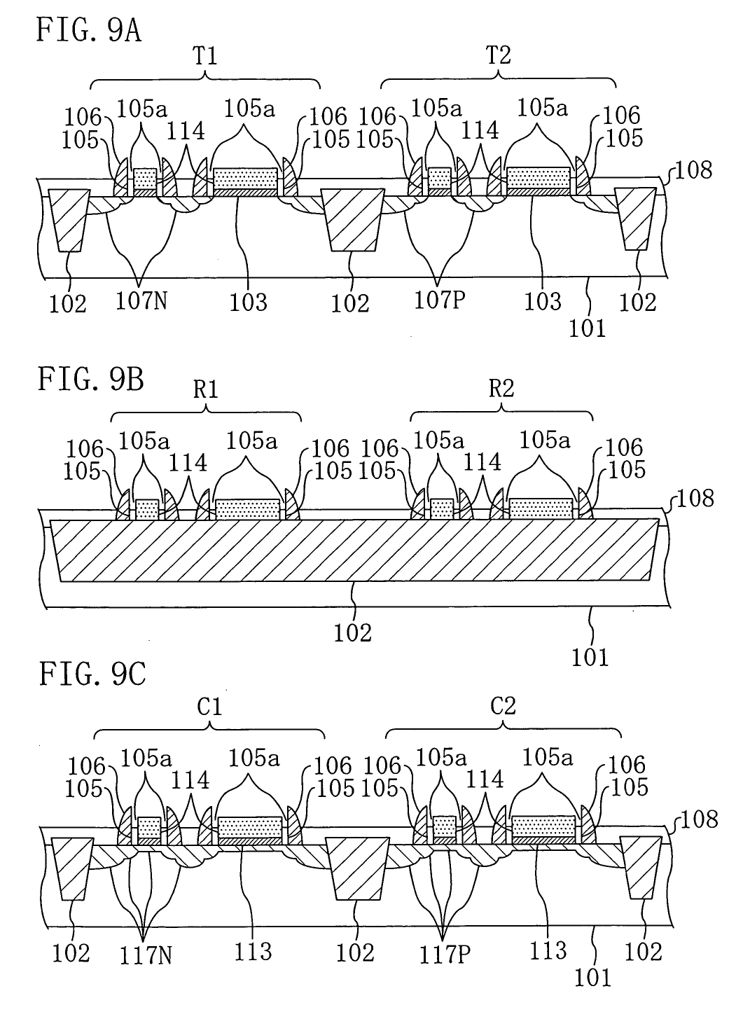

Then, as illustrated in FIGS. 9A through 9C, the protective insulating film 115 is removed by, for example, wet etching, thereby exposing the polysilicon film 114 underlying the protective insulating film 115. At this time, since both the first sidewall spacers 105 and the protective insulating film 115 are made of silicon oxide, the etching is performed such that the upper ends of the first sidewall spacers 105 are lower than the upper surfaces of the adjacent portions of the polysilicon film 114. Alternatively, dry etching may be used instead of wet etching. In this case, gaps 105a having a high aspect ratio are formed between the second sidewall spacers 106 and the polysilicon film 114. At this time, the distance (i.e., the depth of the gaps 105a) from the upper surface of the polysilicon film 114 to the upper ends of the first sidewall spacers 105 is preferably equal to or larger than the width of the first sidewall spacers 105. In the second embodiment, the protective insulating film 115 is previously deposited on the polysilicon film 114, and then upper portions of the first sidewall spacers 105 are etched during removal of the protective insulating film 115 by etching. Alternatively, different materials may be used for the protective insulating film 115 and the first sidewall spacers 105 so that the protective insulating film 115 and the second sidewall spacers 106 are etched in separate processes. The interlayer insulating film 108 may also be deposited directly on the polysilicon film 114 with no protective insulating film 115 deposited so that upper portions of the respective first sidewall spacers 105 are removed by etching after exposure of the upper surfaces of the polysilicon film 114 by, for example, CMP.

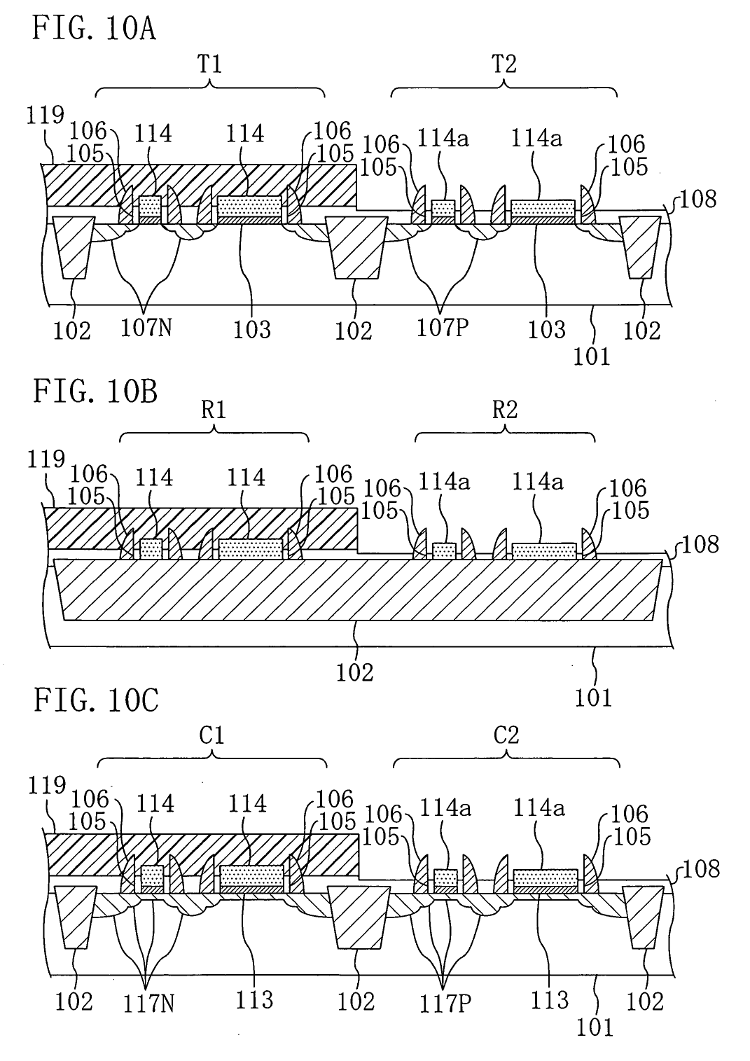

Thereafter, as illustrated in FIGS. 10A through 10C, a resist film 119 masking the n-FET region T1, the first resistor region R1 and the first capacitor region C1 is formed by lithography. Then, dry etching is performed on portions of the polysilicon film 114 in the p-FET region T2, the second resistor region R2 and the second capacitor region C2 using an etching gas containing chlorine or hydrogen bromide as a main component with the resist film 119 used as a mask, thereby obtaining a polysilicon film 114a with a thickness of 40 nm. At this time, in the p-FET region T2, the second resistor region R2 and the second capacitor region C2, the upper ends of the first sidewall spacers 105 need to be lower than the upper surfaces of the polysilicon film 114a. The distance (i.e., the depth of the gaps 105a) between the upper surface of the polysilicon film 114a and the upper ends of the first sidewall spacers 105 is preferably equal to or larger than the width of the first sidewall spacers 105. Accordingly, in the process step shown in FIGS. 9A through 9C, the height of the first sidewall spacers 105 in, for example, the p-FET region T2 may be previously reduced, or in the process step shown in FIGS. 10A through 10C, etching for adjusting the height of the first sidewall spacers 105 may be performed again.

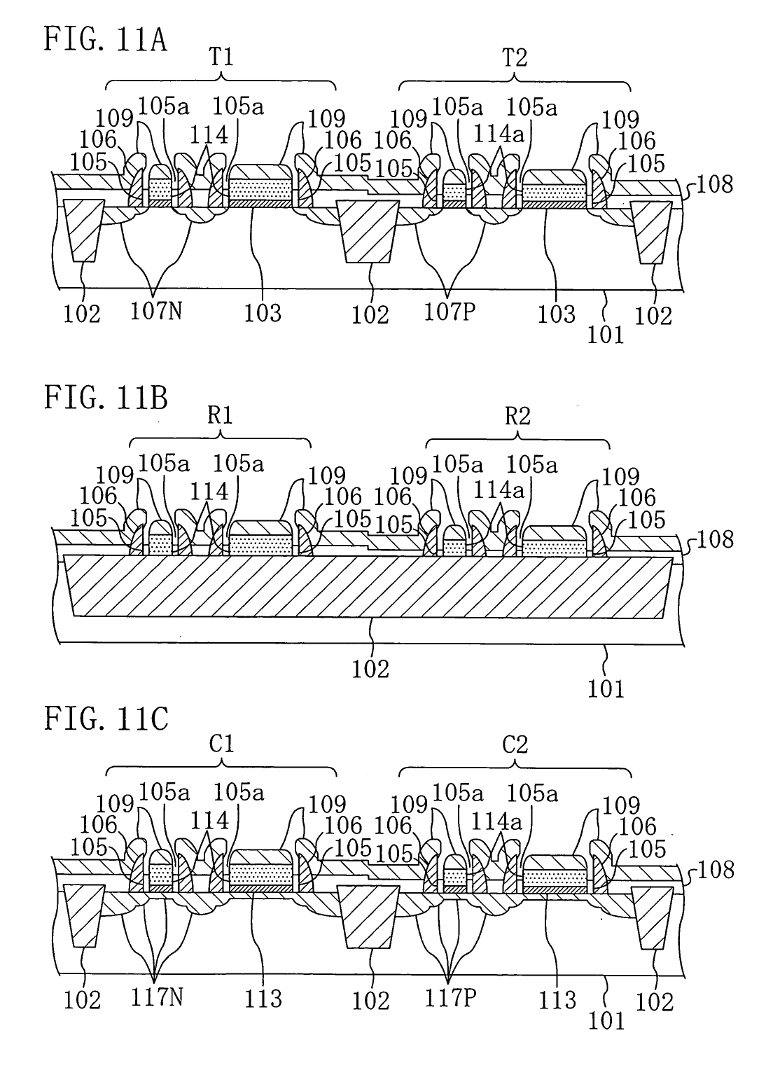

Subsequently, as illustrated in FIGS. 11A through 11C, a metal film 109 made of nickel (Ni) and having a thickness of 45 nm, for example, is deposited by sputtering over the interlayer insulating film 108 including the exposed sidewall spacers 105 and 106 and the polysilicon films 114 and 114a. At this time, as described above, the deposition of the metal film 109 generally has poor step coverage, so that substantially no metal film 109 is deposited in gaps 105a on the first sidewall spacers 105 between the second sidewall spacers 106 and the polysilicon films 114 and 114a, irrespective of the sizes of the polysilicon films 114 and 114a. Accordingly, the gaps 105a remain. It should be noted that the metal film 109 is deposited across the gaps 105a in some cases. However, in such cases, the thickness of the metal film 109 is small, and no substantial problem occurs.

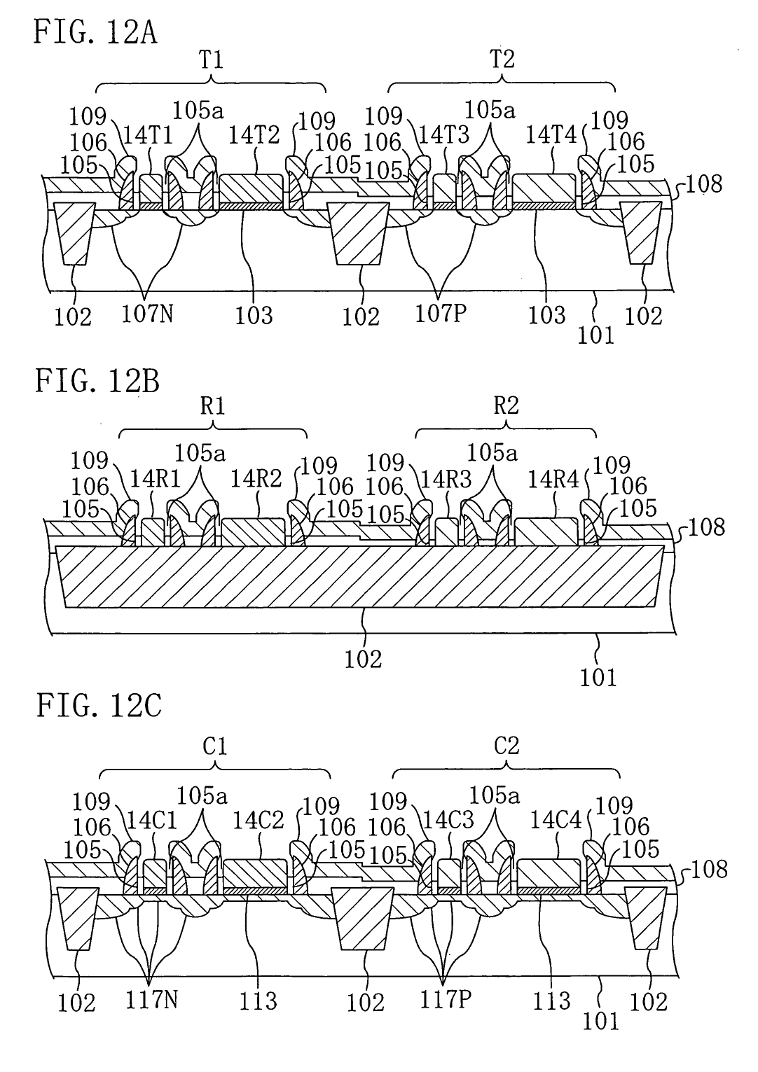

Then, as illustrated in FIGS. 12A through 12C, heat treatment is performed on the semiconductor substrate 101 by, for example, rapid thermal annealing (RTA) at 400° C. in a nitrogen atmosphere to cause silicidation between the polysilicon films 114 and 114a and the metal film 109, thereby siliciding the entire polysilicon films 114 and 114a. In this manner, a first gate electrode 14T1 and a second gate electrode 14T2 both having FUSI structures of NiSi and having different gate lengths are formed in the n-FET region T1 on the semiconductor substrate 101, a first resistor element 14R1 and a second resistor element 14R2 both having FUSI structures of NiSi and having different widths are formed in the first resistor region R1 on the semiconductor substrate 101, and a first upper electrode 14C1 and a second upper electrode 14C2 both having FUSI structures of NiSi and having different widths are formed in the first capacitor region C1 on the semiconductor substrate 101. On the other hand, a third gate electrode 14T3 and a fourth gate electrode 14T4 both having FUSI structures of Ni₃Si and having different gate lengths are formed in the p-FET region T2, a third resistor element 14R3 and a fourth resistor element 14R4 both having FUSI structures of Ni₃Si and having different widths are formed in the second resistor region R2, and a third upper electrode 14C3 and a fourth upper electrode 14C4 both having FUSI structures of Ni₃Si and having different widths are formed in the second capacitor region C2.

The second embodiment is characterized in that the gaps 105a are formed by removing upper portions of the first sidewall spacers 105 between the second sidewall spacers 106 and the polysilicon films 114 and 114a during a silicidation process, so that portions of the metal film 109 are isolated from each other on the polysilicon films 114 and 114a or portions of the metal film 109 across the gaps 105a are thinner than the other portions. This prevents metal for silicidation from being excessively supplied to the polysilicon films 114 and 114a from portions over upper ends of the second sidewall spacers 106 and their neighboring portions. Accordingly, the volume ratio between portions of the polysilicon films 114 and 114a capable of reacting and portions of the metal film 109 capable of reacting does not depend on the gate lengths, i.e., the planar dimensions, of the gate electrodes 14T1 and 14T2, for example. Specifically, the volume ratio between the reactable portions of the polysilicon films 114 and 114a and the reactable portions of the metal film 109 is determined by the thickness of the polysilicon films 114 and 114a exposed in the process step shown in FIGS. 9A through 9C and FIGS. 10A through 10C and the thickness of the metal film 109 deposited in the process step shown in FIGS. 11A through 11C, and is substantially uniform. In this manner, even the gate electrodes 14T1 and 14T2, 14T3 and 14T4, the resistor elements 14R1 and 14R2, 14R3 and 14R4, and the upper electrodes 14C1 and 14C2, 14C3 and 14C4, each pair of which has different planar dimensions, are allowed to have FUSI structures with a uniform composition. Since silicidation occurs between the polysilicon films 114 and 114a and their overlying metal film 109, substantially no growth occurs in the lateral direction (i.e., the in-plane direction of the semiconductor substrate 101). Accordingly, the FUSI upper portions of the gate electrodes 14T1 through 14T4 are isolated between the second sidewall spacers 106, and the gaps 105a are maintained. In addition, no silicidation occurs in portions of the metal film 109 deposited over the n- and p-type source/drain regions 107N and 107P and the n- and p-type lower electrodes 117N and 117P because the interlayer insulating film 108 is interposed therebetween.

In addition, in the second embodiment, the polysilicon film 114a for forming gate electrodes in the p-FET region T2, for example, is thinner than the polysilicon film 114 for forming gate electrodes in the n-FET region T1 in the process step shown in FIG. 10A. Accordingly, the volume ratio of the metal film 109 to the polysilicon film 114a in the p-FET region T2 is higher than that in the n-FET region T1. The same holds for the resistor regions R1 and R2 and the capacitor regions C1 and C2. As a result, if nickel is used for the metal film 109, NiSi is formed as FUSI structures in the n-FET region T1, the first resistor region R1 and the first capacitor region C1, whereas Ni₃Si is formed as FUSI structures in the p-FET region T2, the second resistor region R2 and the second capacitor region C2. That is, FUSI structures having different compositions are formed at a time.

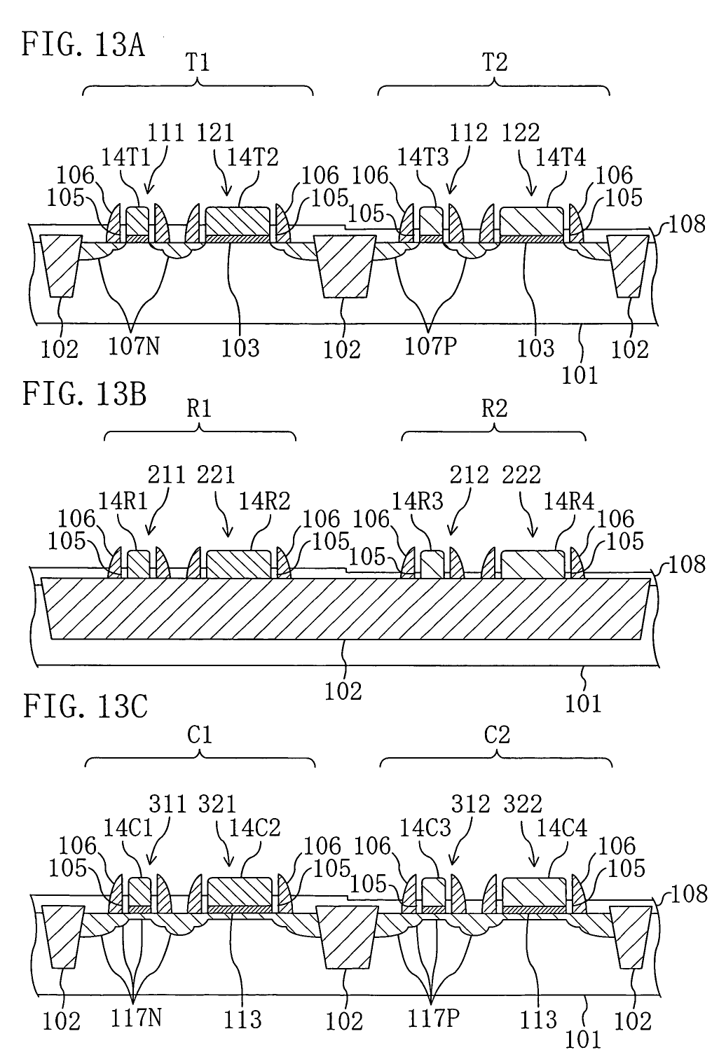

Then, as illustrated in FIGS. 13A through 13C, the unreacted portions of the metal film 109 remaining over the interlayer insulating film 108 and other components are removed by etching using a mixed solution in which hydrochloric acid and a hydrogen peroxide solution, for example, are mixed. Thereafter, an upper-level interlayer insulating film is deposited over the interlayer insulating film 108 including the FUSI gate electrodes 14T1 through 14T4, for example, thereby forming contact holes and interconnections.

As described above, with the method for fabricating a semiconductor device according to the second embodiment, the first sidewall spacers 105 and the second sidewall spacers 106 are stacked on the sides of the polysilicon films 114 and 114a to be silicided, and then the gaps 105a are formed between the second sidewall spacers 106 and the polysilicon films 114 and 114a by removing upper portions of the first sidewall spacers 105. Accordingly, portions of the metal film 109 on the polysilicon films 114 and 114a are isolated from each other after deposition of the metal film 109 on the polysilicon films 114 and 114a. If the portions of the metal film 109 are not isolated from each other, portions of the metal film 109 across the gaps 105a are thinner than the other portions.

In this manner, the NiSi FUSI first and second gate electrodes 14T1 and 14T2, the NiSi FUSI first and second resistor elements 14R1 and 14R2 and the NiSi FUSI first and second upper electrodes 14C1 and 14C2 have the same composition, irrespective of the sizes (planar dimensions) thereof. In the same manner, the Ni₃Si FUSI third and fourth gate electrodes 14T3 and 14T4, the Ni₃Si FUSI third and fourth resistor elements 14R3 and 14R4 and the Ni₃Si FUSI third and fourth upper electrodes 14C3 and 14C4 have the same composition, irrespective of the sizes (planar dimensions) thereof. Moreover, n-FETs 111 and 121, the p-FETs 112 and 122, resistors 211, 221, 212 and 222 and capacitors 311, 321, 312,and 322 are formed at a time.

In the second embodiment, the first resistor 211 and the third resistor 212, for example, have different silicide compositions, but may have the same composition of NiSi or Ni₃Si. For the capacitors, the first capacitor 311 and the third capacitor 312 have different silicide compositions, but may have the same composition.

In the second embodiment, in the process step shown in FIGS. 8A through 8C, the protective insulating film 115 is exposed from the planarized interlayer insulating film 108, and then the protective insulating film 115 and the first sidewall spacers 105 are etched. However, the present invention is not limited to this, and the protective insulating film 115 and the first sidewall spacers 105 may be etched with no interlayer insulating film 108 formed.

### Embodiment 3

Hereinafter a third embodiment of the present invention will be described with reference to the drawings.

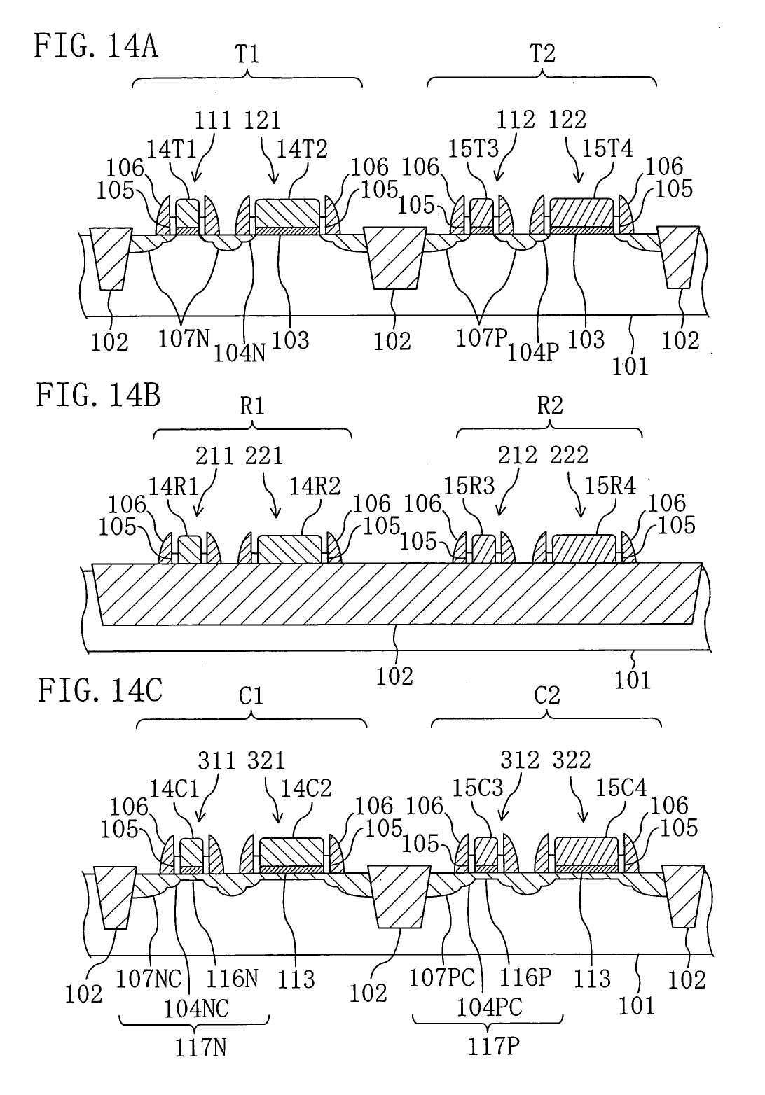

FIGS. 14A through 14C illustrate cross-sectional structures of a semiconductor device according to the third embodiment. In FIGS. 14A through 14C, components also shown in FIGS. 7A through 7C are denoted by the same reference numerals and description thereof will be omitted. The semiconductor device of this embodiment are partitioned into three portions illustrated in FIGS. 14A through 14C for convenience, but is actually formed on one semiconductor substrate 101.

The third embodiment is different from the second embodiment in that a third gate electrode 15T3 and a fourth gate electrode 15T4 formed in a p-FET region T2, a third resistor element 15R3 and a fourth resistor element 15R4 formed in a second resistor region R2 and a third upper electrode 15C3 and a fourth upper electrode 15C4 formed in a second capacitor region C2 are fully silicided with platinum silicide (PtSi).

In the second embodiment, etching is performed to reduce the thickness of the polysilicon film 114 formed by patterning in the p-FET region T2, the second resistor region R2 and the second capacitor region C2, whereas the thickness of the polysilicon film 114 is kept to be equal to that in, for example, the n-FET region T1 in the third embodiment.

In FIGS. 14A through 14C, n-FETs 111 and 121, p-FETs 112 and 122, resistors 211, 221, 212, 222 and capacitors 311, 321, 312 and 322 are formed in the single semiconductor substrate 101, as an example. However, these devices may be individually formed, or two types of the FETs, the resistors and the capacitors may be combined.

With respect to the size of the devices, the FETs, for example, have two gate lengths in this embodiment, but may be three or more gate lengths.

In the third embodiment, the FETs, the resistors and the capacitors are used as exemplary devices, but the present invention is applicable to other devices using conductors with FUSI structures, e.g., fuses.

Hereinafter, a method for fabricating a semiconductor device having the foregoing structure will be described with reference to the drawings.

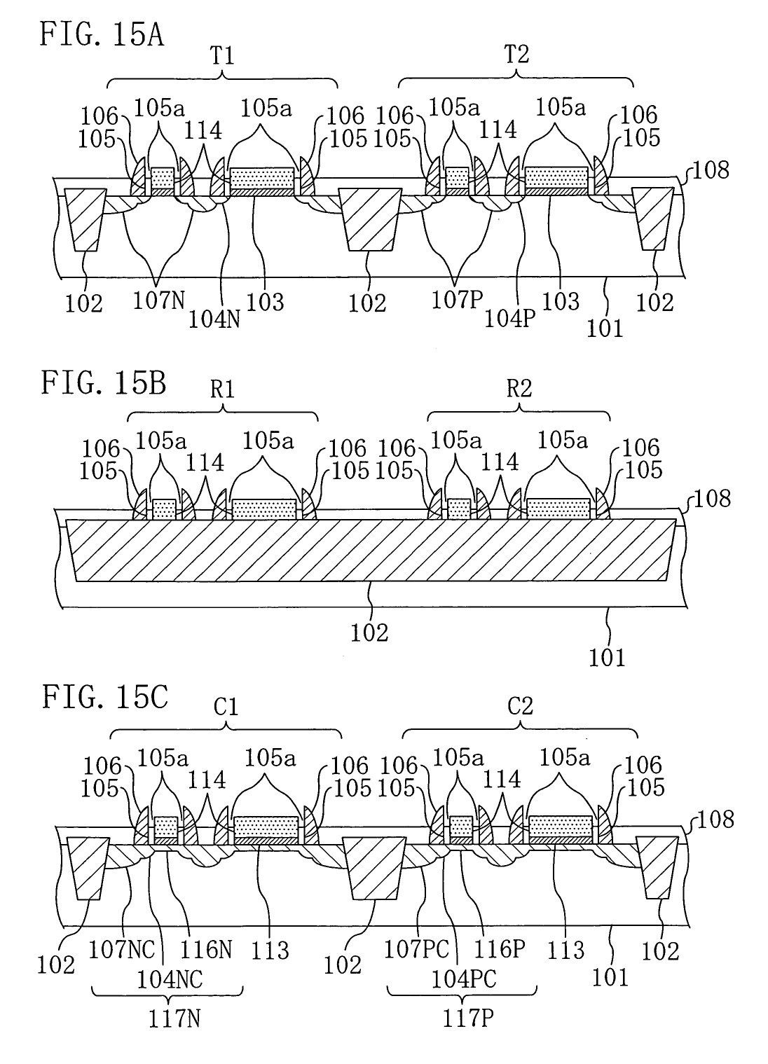

FIGS. 15A through 15C to FIGS. 22A through 22C illustrate cross-sectional structures in respective process steps of a method for fabricating a semiconductor device according to the third embodiment.

First, in the process step shown in FIGS. 15A through 15C, as in FIGS. 9A through 9C for the method of the second embodiment, an interlayer insulating film 108 and first sidewall spacers 105 formed on a semiconductor substrate 101 are removed by etching, so that the upper ends of the first sidewall spacers 105 are lower than the upper ends of second sidewall spacers 106 and the upper surfaces of a polysilicon film 114.

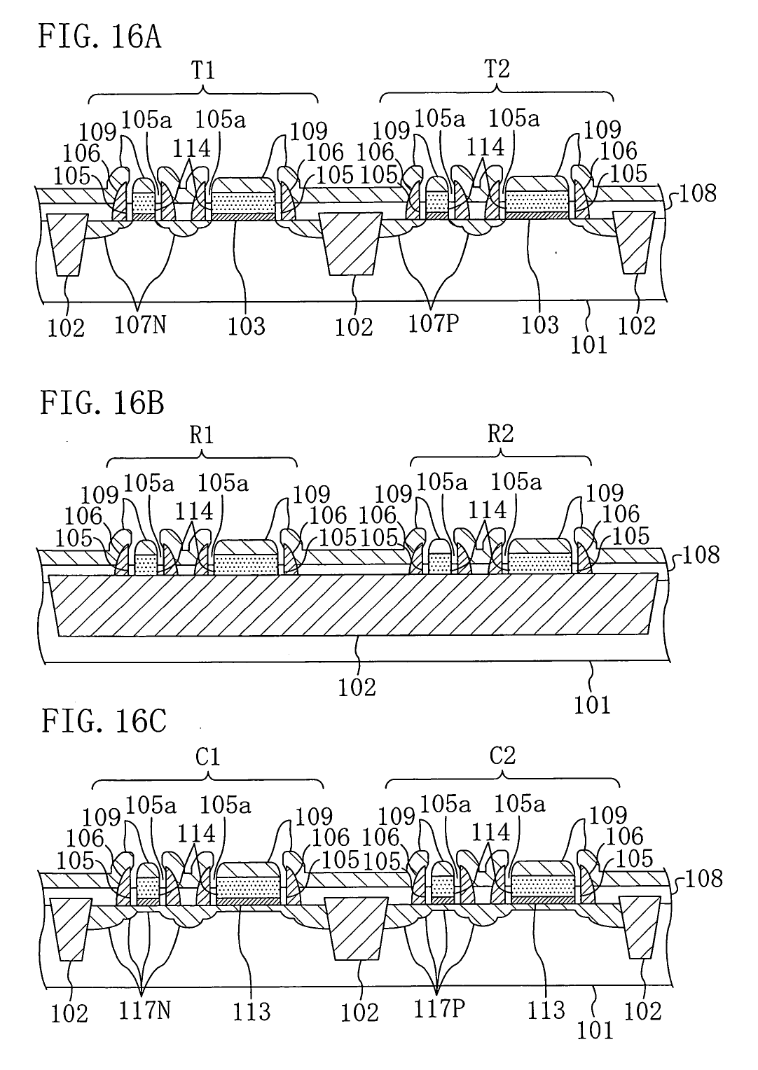

Next, as shown in FIGS. 16A through 16C, a first metal film 109 made of nickel (Ni) and having a thickness of 45 nm, for example, is deposited by sputtering over the interlayer insulating film 108 including the exposed sidewall spacers 105 and 106 and the polysilicon film 114. At this time, as described above, the deposition of the first metal film 109 generally has poor step coverage, so that substantially no first metal film 109 is deposited in gaps 105a on the first sidewall spacers 105 between the second sidewall spacers 106 and the polysilicon film 114, irrespective of the size of the polysilicon film 114. Accordingly, the gaps 105a remain. It should be noted that the first metal film 109 is deposited across the gaps 105a in some cases. However, in such cases, the thickness of the first metal film 109 is small, and no substantial problem occurs.

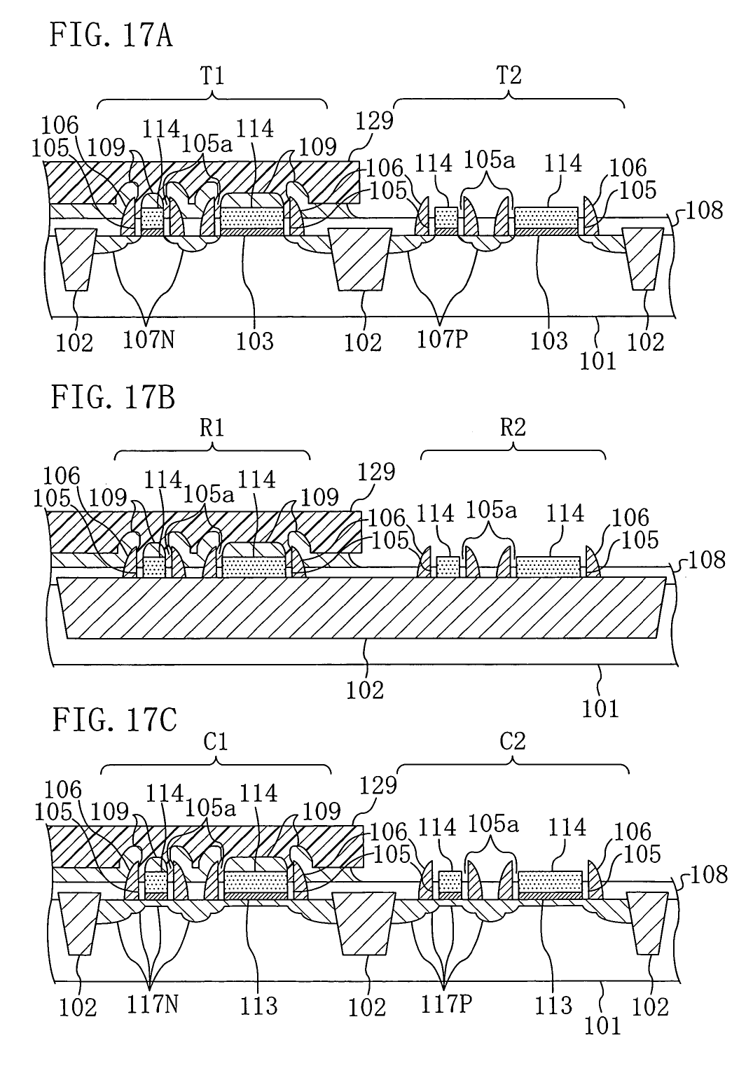

Then, as illustrated in FIGS. 17A through 17C, a first resist film 129 masking an n-FET region T1, a first resistor region R1 and a first capacitor region C1 is formed by lithography. Using the first resist film 129 as a mask, a portion of the first metal film 109 covering a p-FET region T2, a second resistor region R2 and a second capacitor region C2 is removed using a mixed solution in which hydrochloric acid and a hydrogen peroxide solution, for example, are mixed.

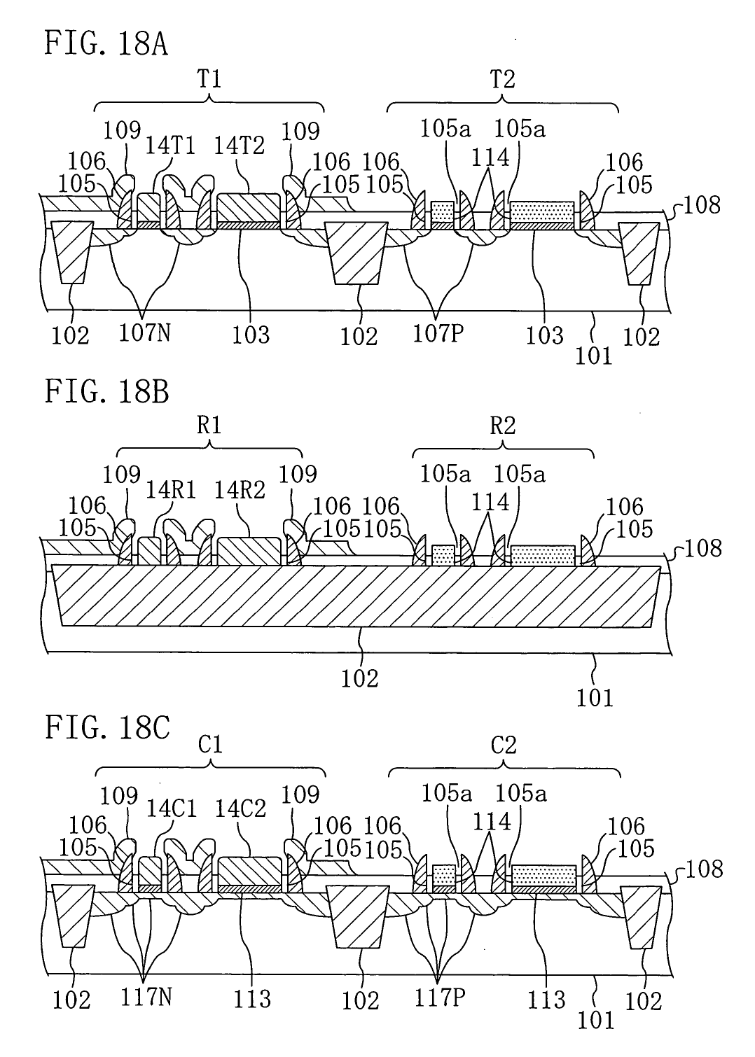

Thereafter, as illustrated in FIGS. 18A through 18C, the first resist film 129 is removed, and then heat treatment is performed on the semiconductor substrate 101 by, for example, rapid thermal annealing (RTA) at 400° C. in a nitrogen atmosphere to cause silicidation between the polysilicon film 114 and the first metal film 109 in the n-FET region T1, the first resistor region R1 and the first capacitor region C1, thereby siliciding the entire polysilicon film 114. In this manner, a first gate electrode 14T1 and a second gate electrode 14T2 both having FUSI structures of NiSi and having different gate lengths are formed in the n-FET region T1, a first resistor element 14R1 and a second resistor element 14R2 both having FUSI structures of NiSi and having different widths are formed in the first resistor region R1, and a first upper electrode 14C1 and a second upper electrode 14C2 both having FUSI structures of NiSi and having different widths are formed in the first capacitor region C1.

The third embodiment is characterized in that the gaps 105a are formed by removing upper portions of the first sidewall spacers 105 between the second sidewall spacers 106 and the polysilicon film 114 during the first silicidation process, so that portions of the first metal film 109 are isolated from each other on the polysilicon film 114 or portions of the first metal film 109 across the gaps 105a are thinner than the other portions. This prevents metal for silicidation from being excessively supplied to the polysilicon film 114 from portions over the upper ends of the second sidewall spacers 106 and their neighboring portions. Accordingly, the volume ratio between the reactable portions of the polysilicon film 114 and the reactable portions of the first metal film 109 is determined by the thickness of the polysilicon film 114 exposed in the process step shown in FIGS. 15A through 15C and the thickness of the first metal film 109 deposited in the process step shown in FIGS. 16A through 16C, and is substantially uniform. In this manner, even the gate electrodes 14T1 and 14T2, the resistor elements 14R1 and 14R2, and the upper electrodes 14C1 and 14C2, each pair of which has different planar dimensions, are allowed to have FUSI structures with a uniform composition. Since silicidation occurs between the polysilicon film 114 and its overlying first metal film 109, substantially no growth occurs in the lateral direction. Accordingly, the FUSI upper portions of the gate electrodes 14T1 and 14T2, for example, are isolated between the second sidewall spacers 106, and the gaps 105a are maintained. In addition, no silicidation occurs in portions of the first metal film 109 deposited over the n-type source/drain regions 107N and the n-type regions 107NC because the interlayer insulating film 108 is interposed therebetween.

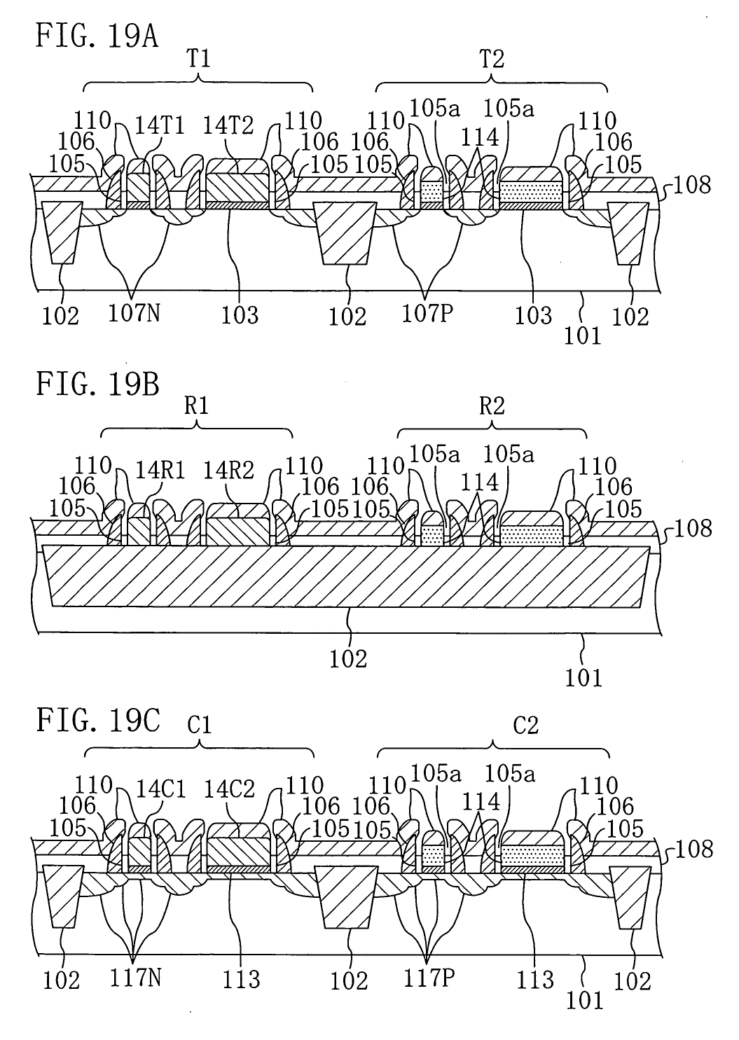

Then, as illustrated in FIGS. 19A through 19C, the unreacted portions of the first metal film 109 are removed with a mixed solution in which hydrochloric acid and a hydrogen peroxide solution, for example, are mixed. Thereafter, a second metal film 110 with a thickness of, for example, 45 nm and made of platinum (Pt) is deposited by sputtering over the interlayer insulating film 108 including the exposed sidewall spacers 105 and 106, the gate electrodes 14T1 and 14T2, the resistor elements 14R1 and 14R2, the upper electrodes 14C1 and 14C2 and the polysilicon film 114. The deposition of the second metal film 110 also has poor step coverage, so that substantially no second metal film 110 is deposited in the gaps 105a on the first sidewall spacers 105 between the second sidewall spacers 106 and the polysilicon film 114, irrespective of the size of the polysilicon film 114. Accordingly, the gaps 105a remain. It should be noted that the second metal film 110 is deposited across the gaps 105a in some cases. However, in such cases, the thickness of the second metal film 110 is small, and no substantial problem occurs.

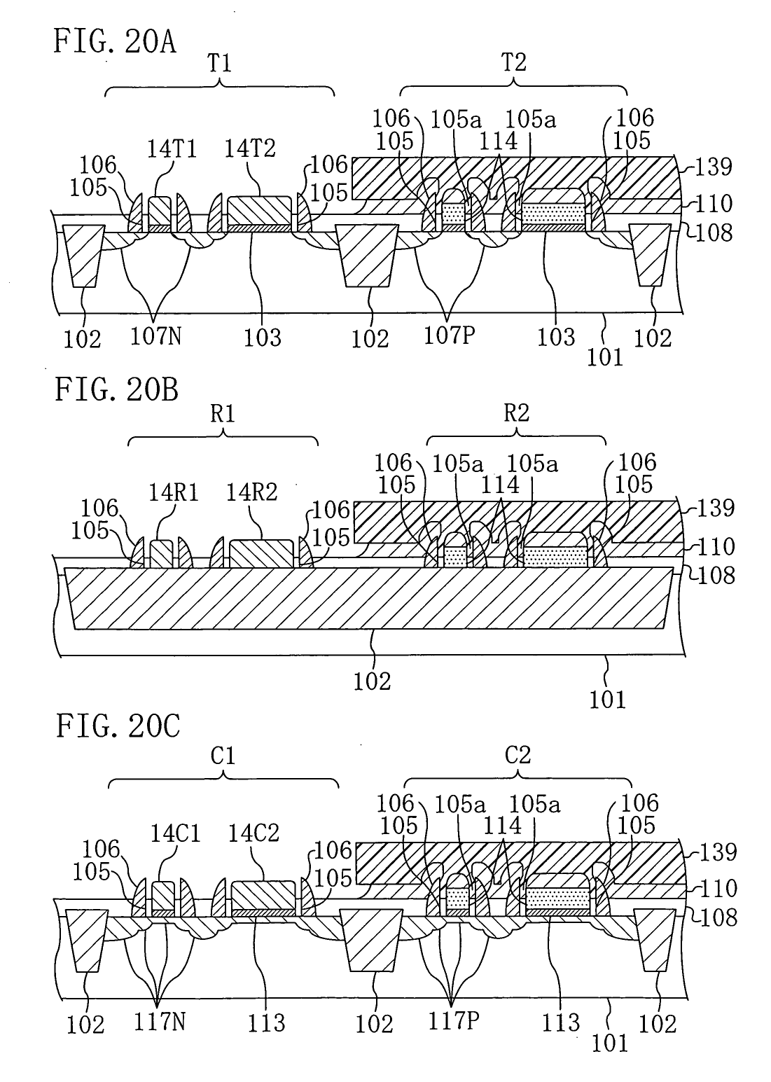

Then, as illustrated in FIGS. 20A through 20C, a second resist film 139 masking the p-FET region T2, the second resistor region R2 and the second capacitor region C2 is formed by lithography. Using the second resist film 139 as a mask, a portion of the second metal film 110 covering the n-FET region T1, the first resistor region R1 and the first capacitor region C1 is removed using a mixed solution in which hydrochloric acid and a hydrogen peroxide solution, for example, are mixed.

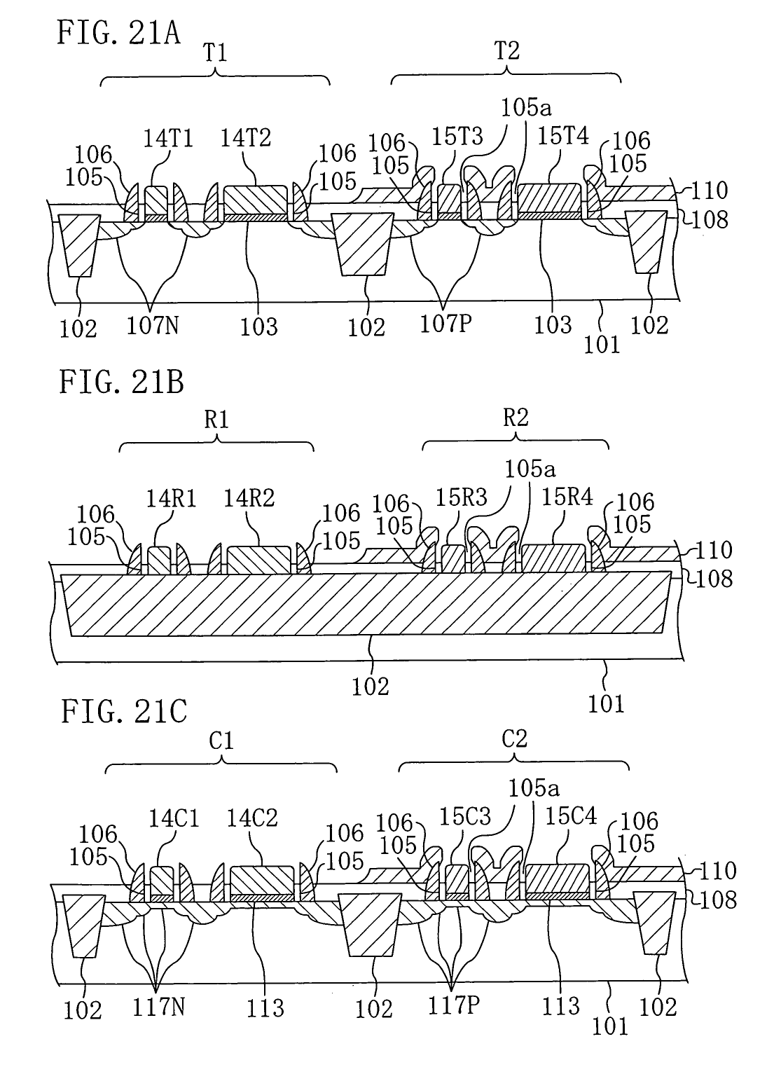

Thereafter, as illustrated in FIGS. 21A through 21C, the second resist film 139 is removed, and then heat treatment is performed on the semiconductor substrate 101 by, for example, rapid thermal annealing (RTA) at 400° C. in a nitrogen atmosphere to cause silicidation between the polysilicon film 114 and the second metal film 110 in the p-FET region T2, the second resistor region R2 and the second capacitor region C2, thereby siliciding the entire polysilicon film 114. In this manner, a third gate electrode 15T3 and a fourth gate electrode 15T4 both having FUSI structures of PtSi and having different gate lengths are formed in the p-FET region T2, a third resistor element 15R3 and a fourth resistor element 15R4 both having FUSI structures of PtSi and having different widths are formed in the second resistor region R2, and a third upper electrode 15C3 and a fourth upper electrode 15C4 both having FUSI structures of PtSi and having different widths are formed in the second capacitor region C2.

The third embodiment is characterized in that the gaps 105a are formed by removing upper portions of the first sidewall spacers 105 between the second sidewall spacers 106 and the polysilicon film 114 during the second silicidation process, so that portions of the second metal film 110 are isolated from each other on the polysilicon film 114 or portions of the second metal film 110 across the gaps 105a are thinner than the other portions. This prevents metal from being excessively supplied to the polysilicon film 114 from portions over the upper ends of the second sidewall spacers 106 and their neighboring portions. Accordingly, the volume ratio between the reactable portions of the polysilicon film 114 and the reactable portions of the second metal film 110 is determined by the thickness of the polysilicon film 114 exposed in the process step shown in FIGS. 18A through 18C and the thickness of the second metal film 110 deposited in the process step shown in FIGS. 19A through 19C, and is substantially uniform. In this manner, even the gate electrodes 15T3 and 15T4, the resistor elements 15R3 and 15R4, and the upper electrodes 15C3 and 15C4, each pair of which has different planar dimensions, are allowed to have FUSI structures with a uniform composition. Since silicidation occurs between the polysilicon film 114 and its overlying second metal film 110, substantially no growth occurs in the lateral direction. Accordingly, the FUSI upper portions of the gate electrodes 15T3 and 15T4, for example, are isolated between the second sidewall spacers 106, and the gaps 105a are maintained. In addition, no silicidation occurs in portions of the second metal film 110 deposited over the p-type source/drain regions 107P and the p-type lower electrode 117P because the interlayer insulating film 108 is interposed therebetween.

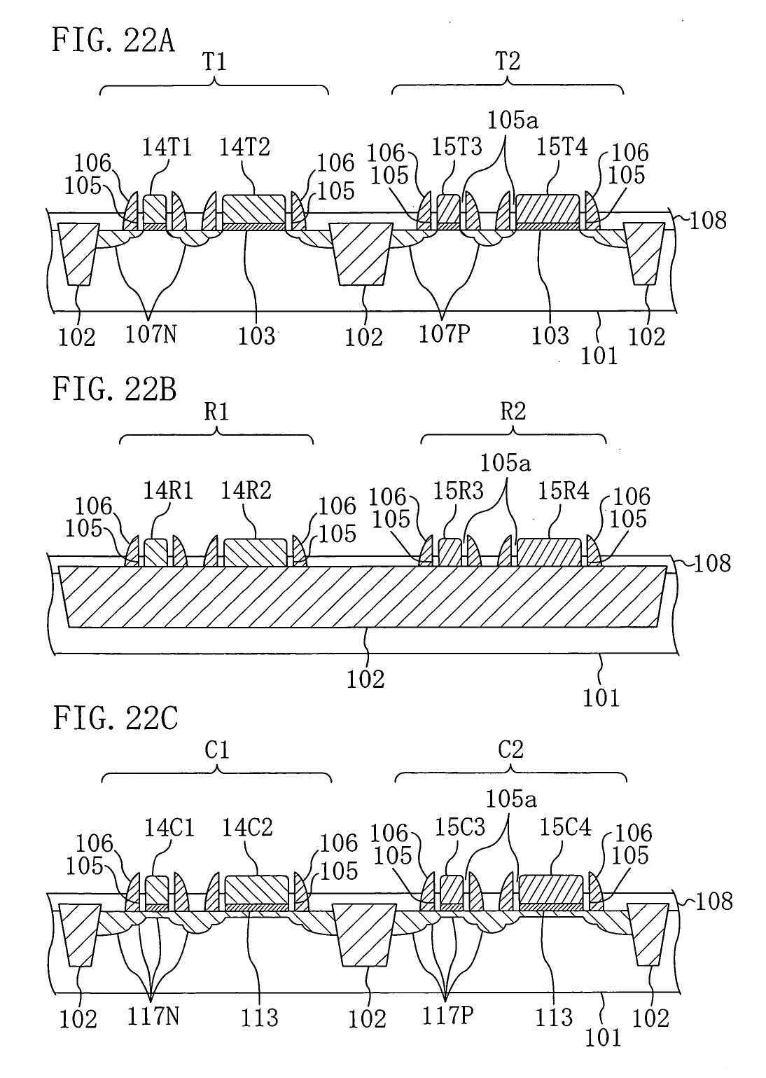

Then, as illustrated in FIGS. 22A through 22C, the unreacted portions of the second metal film 110 are removed by etching using a mixed solution in which hydrochloric acid and a hydrogen peroxide solution, for example, are mixed. Thereafter, an upper-level interlayer insulating film is deposited over the interlayer insulating film 108 including the FUSI gate electrodes 14T1, 14T2, 15T3 and 15T4, for example, thereby forming contact holes and interconnections.

As described above, with the method for fabricating a semiconductor device of the third embodiment, the first sidewall spacers 105 and the second sidewall spacers 106 are stacked on the sides of the polysilicon film 114 to be silicided, and then the gaps 105a are formed between the second sidewall spacers 106 and the polysilicon film 114 by removing upper portions of the first sidewall spacers 105. Accordingly, portions of the first and second metal films 109 and 110 on the polysilicon film 114 are isolated from each other after deposition of the respective metal films 109 and 110 on the polysilicon film 114. Even if the portions of the metal films 109 and 110 are not isolated from each other, the thicknesses of portions of the metal films 109 and 110 across the gaps 105a are smaller than those of the other portions.

In this manner, the NiSi FUSI first and second gate electrodes 14T1 and 14T2, the NiSi FUSI first and second resistor elements 14R1 and 14R2 and the NiSi FUSI first and second upper electrodes 14C1 and 14C2 have the same composition, irrespective of the sizes (planar dimensions) thereof. In the same manner, the PtSi FUSI third and fourth gate electrodes 15T3 and 15T4, the PtSi FUSI third and fourth resistor elements 15R3 and 15R4 and the PtSi FUSI third and fourth upper electrodes 15C3 and 15C4 have the same composition, irrespective of the sizes (planar dimensions) thereof. As a result, it is possible to prevent variations of the threshold voltages caused by nonuniform compositions depending on the sizes of the gate electrodes 14T1, 14T2, 15T3 and 15T4 in the case of the FETs, so that performance of the semiconductor device is enhanced and integration degree is increased.

Moreover, n-FETs 111 and 121, the p-FETs 112 and 122, resistors 211, 221, 212 and 222 and capacitors 311, 321, 312 and 322 are formed at a time.

In the FETs, the gaps 105a on the first sidewall spacers 105 greatly reduce stress on the semiconductor substrate 101 caused by the difference in expansion coefficient between the silicide material and the second sidewall spacers 106 during heat treatment after full silicidation, irrespective of the sizes of the gate electrodes, so that variation in FET characteristics resulting from stress difference is prevented.

In the third embodiment, the first resistor 211 and the third resistor 212, for example, have different silicide compositions, but may have the same composition of NiSi or PtSi. In the case of the capacitors, the first capacitor 311 and the third capacitor 312 have different silicide compositions, but may have the same composition.

In a modified example of the method of the third embodiment, after the deposition of the first metal film 109 shown in FIGS. 16A through 16C, the first metal film 109 may be selectively deposited again only on the p-FET region T2, the second resistor region R2 and the second capacitor region C2 so that the third gate electrodes 15T3 and 15T4 in the p-FET region T2, for example, become metal-rich and are changed to, for example, Ni₃Si.

As described above, with the semiconductor device and the method for fabricating the device according to the present invention have the advantage of uniform FUSI structures. The present invention is especially useful for semiconductor devices including field-effect-transistors having FUSI gate electrodes and methods for fabricating such devices.

What is claimed is:

1. A semiconductor device, comprising a first MIS transistor including a first gate electrode fully silicided with a metal,
wherein the first MIS transistor includes:
a first gate insulating film formed on a semiconductor region;
the first gate electrode formed on the first gate insulating film;
a first sidewall spacer formed on a side of the first gate electrode; and
a second sidewall spacer formed at the side of the first gate electrode with the first sidewall spacer interposed therebetween,
the first sidewall spacer and the second sidewall spacer have different etching characteristics, and
the first sidewall spacer has an upper end lower than an upper surface of the first gate electrode and an upper end of the second sidewall spacer.

2. The semiconductor device of claim 1, wherein the upper end of the second sidewall spacer is higher than the upper surface of the first gate electrode.

3. The semiconductor device of claim 1, further comprising a second MIS transistor including a second gate electrode fully silicided with the metal and having a gate length larger than that of the first gate electrode,
wherein the second MIS transistor includes:
a second gate insulating film formed on the semiconductor region;
the second gate electrode formed on the second gate insulating film;
a first sidewall spacer formed on a side of the second gate electrode; and
a second sidewall spacer formed at the side of the second gate electrode with the first sidewall spacer interposed therebetween,
the first sidewall spacer has an upper end lower than an upper surface of the second gate electrode and an upper end of the second sidewall spacer, and
the first MIS transistor and the second MIS transistor are of an identical conductivity type.

4. The semiconductor device of claim 3, wherein the upper surface of the first gate electrode and the upper surface of the second gate electrode are at an identical level from an upper surface of the semiconductor region.

5. The semiconductor device of claim 3, wherein the first gate electrode and the second gate electrode have an identical composition.

6. The semiconductor device of claim 1, further comprising a third MIS transistor including a third gate electrode fully silicided with the metal,
wherein the third MIS transistor includes:
a third gate insulating film formed on the semiconductor region;
the third gate electrode formed on the third gate insulating film;
a first sidewall spacer formed on a side of the third gate electrode; and
a second sidewall spacer formed at the side of the third gate electrode with the first sidewall spacer interposed therebetween,
the first sidewall spacer has an upper end lower than an upper surface of the third gate electrode and an upper end of the second sidewall spacer, and
the first MIS transistor and the third MIS transistor are of different conductivity types.

7. The semiconductor device of claim 6, wherein the first gate electrode and the third gate electrode have different compositions.

8. The semiconductor device of claim 1, further comprising a resistor including a resistor element fully silicided with the metal,
wherein the resistor includes:
the resistor element formed on an isolation region defined in an upper portion of the semiconductor region;
a first sidewall spacer formed on a side of the resistor element; and
a second sidewall spacer formed at the side of the resistor element with the first sidewall spacer interposed therebetween, and
the first sidewall spacer has an upper end lower than an upper surface of the resistor element and an upper end of the second sidewall spacer.

9. The semiconductor device of claim 8, wherein the first gate electrode and the resistor element have an identical composition.

10. The semiconductor device of claim 1, further comprising a capacitor including an upper electrode fully silicided with the metal,
wherein the capacitor includes:
a capacitive insulating film formed on the semiconductor region;
the upper electrode formed on the capacitive insulating film;
a first sidewall spacer formed on a side of the upper electrode; and
a second sidewall spacer formed at the side of the upper electrode with the first sidewall spacer interposed therebetween, and
the first sidewall spacer has an upper end lower than an upper surface of the upper electrode and an upper end of the second sidewall spacer.

11. The semiconductor device of claim 10, wherein the first gate electrode and the upper electrode have an identical composition.

12. A method for fabricating a semiconductor device including a first MIS transistor including a first gate electrode on a first gate insulating film, the method comprising the steps of:
(a) forming the first gate insulating film on a semiconductor region;
(b) forming a first gate silicon film on the first gate insulating film;
(c) forming a first sidewall spacer on a side of the first gate silicon film;
(d) forming a second sidewall spacer at the side of the first gate silicon film with the first sidewall spacer interposed therebetween;
(e) etching the first sidewall spacer after the step (d) such that the first sidewall spacer has an upper end lower than an upper surface of the first gate silicon film and an upper end of the second sidewall spacer;
(f) forming a metal film on the first gate silicon film after the step (e); and
(g) fully siliciding the first gate silicon film with the metal film, thereby forming the first gate electrode.

13. The method of claim 12, wherein the step (b) includes the step of forming a protective insulating film on the first gate silicon film,
the step (c) includes the step of forming the first sidewall spacer on sides of the first gate silicon film and the protective insulating film,
the step (d) includes the step of forming the second sidewall spacer at the sides of the first gate silicon film and the protective insulating film with the first sidewall spacer interposed therebetween, and
the step (e) includes the step of etching the protective insulating film, thereby exposing the upper surface of the first gate silicon film.

14. The method of claim 12, wherein the semiconductor device further includes a second MIS transistor including, on a second gate insulating film, a second gate electrode having a gate length larger than that of the first gate electrode,
the step (a) includes the step of forming the second gate insulating film on the semiconductor region;
the step (b) includes the step of forming a second gate silicon film on the second gate insulating film;
the step (c) includes the step of forming a first sidewall spacer on a side of the second gate silicon film,
the step (d) includes the step of forming a second sidewall spacer at the side of the second gate silicon film with the first sidewall spacer interposed therebetween,
the step (e) includes the step of etching the first sidewall spacer such that the first sidewall spacer has an upper end lower than an upper surface of the second gate silicon film and an upper end of the second sidewall spacer,
the step (f) includes-the step of forming the metal film on the second gate silicon film, and
the step (g) includes the step of fully siliciding the second gate silicon film with the metal film, thereby forming the second gate electrode.

15. The method of claim 12, wherein the semiconductor device further includes a third MIS transistor including, on a third gate insulating film, a third gate electrode having a composition different from that of the first gate electrode,
the step (a) includes the step of forming the third gate insulating film on the semiconductor region,
the step (b) includes the step of forming a third gate silicon film on the third gate insulating film,
the step (c) includes the step of forming a first sidewall spacer on a side of the third gate silicon film,
the step (d) includes the step of forming a second sidewall spacer at the side of the third gate silicon film with the first sidewall spacer interposed therebetween,
the step (e) includes the step of etching the first sidewall spacer such that the first sidewall spacer has an upper end lower than an upper surface of the third gate silicon film and an upper end of the second sidewall spacer,
the step (f) includes the step of forming the metal film on the third gate silicon film,
the step (g) includes the step of fully siliciding the third gate silicon film with the metal film, thereby forming the third gate electrode, and
the method further comprises the step of (h) etching the third gate silicon film such that the upper surface of the third gate silicon film is lower than the upper surface of the first gate silicon film, after the step (b) and before the step (f).

16. The method of claim 12, wherein the semiconductor device further includes a third MIS transistor including, on a third gate insulating film, a third gate electrode having a composition different from that of the first gate electrode,
the step (a) includes the step of forming the third gate insulating film on the semiconductor region,
the step (b) includes the step of forming a third gate silicon film on the third gate insulating film,
the step (c) includes the step of forming a first sidewall spacer on a side of the third gate silicon film,
the step (d) includes the step of forming a second sidewall spacer at the side of the third gate silicon film with the first sidewall spacer interposed therebetween,
the step (e) includes the step of etching the first sidewall spacer such that the first sidewall spacer has an upper end lower than an upper surface of the third gate silicon film and an upper end of the second sidewall spacer, and
the method further comprises, after the step (e), the steps of:
(i) forming another metal film on the third gate silicon film; and
(j) fully siliciding the third gate silicon film with said another metal film, thereby forming the third gate electrode.

17. The method of claim 12, wherein the semiconductor device further includes a resistor including a resistor element,
the method further comprises the step of (k) forming an isolation region in an upper portion of the semiconductor region before the step (a),
the step (b) includes the step of forming a resistor silicon film on the isolation region,
the step (c) includes the step of forming a first sidewall spacer on a side of the resistor silicon film,
the step (d) includes the step of forming a second sidewall spacer at the side of the resistor silicon film with the first sidewall spacer interposed therebetween,
the step (e) includes the step of etching the first sidewall spacer such that the first sidewall spacer has an upper end lower than an upper surface of the resistor silicon film and an upper end of the second sidewall spacer,
the step (f) includes the step of forming the metal film on the resistor silicon film, and
the step (g) includes the step of fully siliciding the resistor silicon film with the metal film, thereby forming the resistor element.

18. The method of claim 12, wherein the semiconductor device further includes a capacitor including an upper electrode,
the step (a) includes the step of forming a capacitive insulating film on the semiconductor region,
the step (b) includes the step of forming a capacitor silicon film on the capacitive insulating film,
the step (c) includes the step of forming a first sidewall spacer on a side of the capacitor silicon film,
the step (d) includes the step of forming a second sidewall spacer at the side of the capacitor silicon film with the first sidewall spacer interposed therebetween,
the step (e) includes the step of etching the first sidewall spacer such that the first sidewall spacer has an upper end lower than an upper surface of the capacitor silicon film and an upper end of the second sidewall spacer,
the step (f) includes the step of forming the metal film on the capacitor silicon film, and
the step (g) includes the step of fully siliciding the capacitor silicon film with the metal film, thereby forming the upper electrode.
